(19) United States
(12) Patent Application Publication
(10) Pub. No.: US 2026/0218417 A1
(43) Pub. Date: Jul. 30, 2026

(54) HIGH REFRACTIVE INDEX ORGANIC SOLID CRYSTAL PARTICLES AND SUBSTRATES

(71) Applicant: Meta Platforms Technologies, LLC, Menlo Park, CA (US)

(72) Inventors: Hend Baza, Redmond, WA (US); Sheng Ye, Redmond, WA (US); Lafe Joseph Purvis, II, Redmond, WA (US); Jason Leigh Potticary, Redmond, WA (US); Andrew John Ouderkirk, Kirkland, WA (US); Viachaslau Bernat, Bothell, WA (US); Liliana Ruiz Diaz, Seattle, WA (US)

(21) Appl. No.: 19/408,663

(22) Filed: Dec. 4, 2025

Related U.S. Application Data
(60) Provisional application No. 63/751,104, filed on Jan. 29, 2025.
(60) Provisional application No. 63/751,099, filed on Jan. 29, 2025.

(51) Int. Cl. C30B 29/54; C30B 33/02

(52) U.S. Cl. CPC C30B 29/54; C30B 33/02

(57) ABSTRACT

An organic solid crystal material has a particulate solid body having a crystalline structure formed from an organic compound, where a particle size of the particulate solid body ranges from 10 nanometers to 10 micrometers, and a refractive index of the particulate solid body is 1.5 to 3.5 along at least one dimension of the particulate solid body.

### CROSS-REFERENCE TO RELATED APPLICATIONS

This application claims the benefit of priority under 35 U.S.C. §119(e) of U.S. Provisional Application No. 63/751,099, filed January 29, 2025, and U.S. Provisional Application No. 63/751,104, filed January 29, 2025, the contents of which are incorporated herein by reference in their entirety.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 is a schematic illustration of example organic solid crystal (OSC) particle geometries according to some embodiments.

FIG. 2 illustrates the formation of nanoscale organic solid crystal particles using microbead-based milling according to some embodiments.

FIG. 3 depicts a solution-based manufacturing method for forming organic solid crystal particles according to various embodiments.

FIG. 4 is a schematic illustration of a microfluidic device for manufacturing particles of an organic solid crystal material according to some embodiments.

FIG. 5 shows compositions and structures of organic solid crystal precursor compounds according to some embodiments.

FIG. 6 depicts compositions and structures of organic solid crystal precursor compounds according to further embodiments.

FIG. 7 shows compositions and structures of organic solid crystal precursor compounds according to still further embodiments.

FIG. 8 depicts example small molecule OSC precursor compounds according to certain embodiments.

FIG. 9 is a schematic illustration of example organic solid crystal-containing substrates according to some embodiments.

FIG. 10 is an illustration of an example artificial-reality system according to some embodiments of this disclosure.

FIG. 11 is an illustration of an example artificial-reality system with a handheld device according to some embodiments of this disclosure.

FIG. 12A is an illustration of example user interactions within an artificial-reality system according to some embodiments of this disclosure.

FIG. 12B is an illustration of example user interactions within an artificial-reality system according to some embodiments of this disclosure.

FIG. 13A is an illustration of example user interactions within an artificial-reality system according to some embodiments of this disclosure.

FIG. 13B is an illustration of example user interactions within an artificial-reality system according to some embodiments of this disclosure.

FIG. 14 is an illustration of an example wrist-wearable device of an artificial-reality system according to some embodiments of this disclosure.

FIG. 15 is an illustration of an example wearable artificial-reality system according to some embodiments of this disclosure.

FIG. 16 is an illustration of an example augmented-reality system according to some embodiments of this disclosure.

FIG. 17A is an illustration of an example virtual-reality system according to some embodiments of this disclosure.

FIG. 17B is an illustration of another perspective of the virtual-reality system shown in FIG. 17A according to some embodiments

FIG. 18 is a block diagram showing system components of example artificial- and virtual-reality systems according to some embodiments.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within this disclosure.

### DETAILED DESCRIPTION OF EXEMPLARY EMBODIMENTS

Polymer and other organic materials may be incorporated into a variety of different optic and electro-optic device architectures, including passive and active optics and electroactive devices. Lightweight and conformable, one or more polymer/organic solid layers may be incorporated into wearable devices such as smart glasses and are attractive candidates for emerging technologies including virtual reality/augmented reality devices where a comfortable, adjustable form factor is desired.

Mixed reality (MR) and augmented reality (AR) eyewear devices or headsets, for instance, may enable users to experience events, such as interactions with people in a computer-generated simulation of a three-dimensional world or viewing data superimposed on a real-world view. Superimposing information onto a field of view may be achieved through an optical head-mounted display (OHMD) or by using embedded wireless glasses with a transparent heads-up display (HUD) or augmented reality (AR) overlay. MR/AR eyewear devices and headsets may be used for a variety of purposes. Governments may use such devices for military training, medical professionals may use such devices to simulate surgery, and engineers may use such devices as design visualization aids.

In optoelectronics, state of the art materials include inorganic, liquid crystal, and polymer materials. These materials are quickly reaching their application limits, however, due to issues such as weight, limited refractive index, limited birefringence, and lack of tunability. Due to restraints associated with various materials systems, devices are restricted in size/weight, optoelectronic performance, such as angular bandwidth and resolution, and manufacturability.

In this regard, Applicants have shown that small molecular solid organic materials allow for the formation of novel active and passive optoelectronic elements that can be inexpensive, and light weight.

Organic solid crystals include organic compounds that form solid crystalline structures. The molecular structure of the organic solids allows for flexibility, facile modification, and a broad range of potential functionalities and applications. Organic solid crystals possess a range of properties that make them attractive for use in various technologies.

One characteristic of organic solid crystals is their electrical properties. Many organic crystals are semiconductors. This makes them suitable for use in electronic devices such as transistors, sensors, and memory storage systems. Another important attribute of organic solid crystals is their optical properties. These materials may have a large refractive index (n>1.5) and often exhibit fluorescence and absorption in the visible and infrared spectrums, allowing them to be used in light-emitting devices, displays, and photo detectors. Their ability to emit light efficiently makes them valuable in applications such as organic light-emitting diodes.

In accordance with various embodiments, organic semiconductors may include small molecules, macromolecules, liquid crystals, organometallic compounds, oligomers, and polymers. Organic semiconductors may include p-type, n-type, or ambipolar polycyclic aromatic hydrocarbons, such as anthracene, phenanthrene, pyrene, corannulene, fluorene, biphenyl, etc. Example compounds may include cyclic, linear and/or branched structures, which may be saturated or unsaturated, and may additionally include heteroatoms and saturated or unsaturated heterocycles, such as furan, pyrrole, thiophene, pyridine, pyrimidine, piperidine, and the like. Heteroatoms may include fluorine, chlorine, nitrogen, oxygen, sulfur, phosphorus, as well as various metals. Further example small molecules include fullerenes, such as carbon 60.

In addition, organic crystals are often more mechanically compliant than inorganic materials, which opens up possibilities for flexible electronics and wearable devices. Their low density also contributes to their lightweight nature making them ideal for portable and wearable technologies.

The properties of organic solid crystals may be tunable. By adjusting the molecular structure of these materials, their electronic and optical characteristics can be preadjusted or modified in real time to meet specific needs, allowing for greater customization in various applications.

As disclosed herein, particulate organic solid crystal (OSC) materials may be incorporated into monolithic bodies, such as optical elements (e.g., lenses, waveguides, and the like) and other structures and may be used in the design and manufacture of commercially relevant devices and systems. For instance, particles of an OSC material may be manufactured and consolidated/densified to form an optical element. The size and shape of the OSC particles may be arranged to provide one or more advantageous characteristics. For instance, according to some embodiments, an optical element formed from particles of an organic solid crystal material may possess one or more of a controllable refractive index and birefringence, optical clarity, and optical transparency. The OSC particles may be nanometer scale or micrometer scale particles, having regular or irregular shapes, such as spheres, plates, disks, rods, etc.

Various synthesis methods may be used to form OSC particles. According to some embodiments, OSC particles may be formed via nucleation and growth from solution or melt. Illustrative methods include crystallization from a saturated solution of one or more precursor compounds and/or solvent evaporation from a solution of one or more precursor compounds. In example methods, OSC particles may be formed by cooling a supersaturated solution or via solvent evaporation of a supersaturated solution. Further synthesis methods include vapor deposition of a precursor solution.

In certain embodiments, a precursor solution may be exposed to ultrasonic waves (> 5 kHz) that are arranged to induce nucleation within the solution. A residence time and temperature to control the growth rate of nascent crystals may be selected, e.g., based on the chosen organic molecule(s). By way of example, a supersaturated solution of 2H-1,2,3-triazole-4,5-dicarbonitrile in water may be prepared at ~25°C (room temperature), heated to 70°C, and sonicated while located within a room temperature water bath to obtain crystals having a mean particle size of approximately 500 nm.

In some embodiments, OSC particles may be manufactured from an emulsion of an OSC solution containing micrometer scale or nanometer scale droplets of precursor dispersed in an immiscible solvent. The emulsion may be contained within the channels of a microfluidic device. The temperature of the emulsion may be controlled to allow a desired droplet size to form prior to nucleation. The emulsion flow rate and the channel dimensions may be controlled to influence the droplet size. The emulsion may be cooled to encourage nucleation and crystal growth. The OSC particles may be collected and dried.

According to further embodiments, OSC particles may be formed via reprecipitation, where a low concentration solution of precursor molecules is injected into a miscible antisolvent. The concentration of the solution and a spinning velocity of the antisolvent may be selected to control the size of the resulting OSC particles. In an example process, 5 ml of 10 wt.% 5-chloro-2-methyl-4-isothiazolin-3-one (CMIT) dissolved into N,N-dimethylformamide (DMF) was injected into 100 ml of water spinning at 1500 rpm, forming a distribution of OSC particles having a particle distribution peak at approximately 500 nm.

In addition to the choice of solvent, one or more of the pH of the solution, a heating or cooling rate, a rate and/or type of mixing (e.g., ultrasonic mixing), and the addition of processing aids may be used to manipulate the size and shape of crystals during growth. OSC particles may be single crystal or polycrystalline. A batch of OSC particles may include a monomorphic or polymorphic mixture of crystalline (e.g., single crystal) particles.

In certain embodiments, an induced crystal-to-crystal or crystal-to-amorphous phase transformation may be effective to change a refractive index of the OSC particles. Such a phase transformation may be performed via photoisomerization using UV irradiation. By way of example, all trans-1,6-diphenyl-1,3,5-hexatriene (DPH) particles have a predicted index (nₓ, n_{y}, n_{z}) of [1.55, 1.66, 2.59]. Upon UV irradiation, a mixture of (trans, trans, cis)-, (trans, cis, trans)-, (cis, trans, cis)- and (cis, cis, trans)- isomers may be formed, which may change the effective refractive index of the OSC particles.

In addition to, or in lieu of the foregoing, post-synthesis particle size refinement may include thermally shocking larger particles, where an abrupt change in temperature may induce fracture and, for example, the formation of an OSC powder from OSC granules. According to further embodiments, larger OSC particles may be milled to produce finer particle sizes. Milling may include dry milling, cryogenic milling, wet milling, media milling, or combinations thereof. In some cases, wet milling may be performed using an organic solvent or a mixture of organic solvents, which may be adapted to disperse OSC particles without dissolving them.

In various embodiments, a particle size may range from approximately 10 nm to approximately 10 micrometers, e.g., 10, 20, 50, 100, 200, 500, 1000, 2000, 5000, or 10000 nm, including ranges between any of the foregoing values. The shape of an OSC particle or powder is not especially limited and example OSC particles may be spherical particles, plate like particles, disk like particles, or rod like particles. An example batch of OSC particles may include a mixture of different shapes and sizes.

In some embodiments, an organic solid crystal material may have a density of 1.1 to 2 g/cm³ and an Abbe number of 2 to 60. In some embodiments, an organic solid crystal-based material may have a transmittance across the visible spectrum (400-700 nm) of at least approximately 80% or a transmittance across the near infrared spectrum (700-2000 nm) of at least approximately 60%.

The organic crystalline phase may be single crystal or polycrystalline. In some embodiments, the organic crystalline phase may include amorphous regions. In some embodiments, the organic crystalline phase may be substantially crystalline. The organic crystalline phase may be characterized by a refractive index along at least one principal axis of at least approximately 1.5 at 589 nm. By way of example, the refractive index of the organic crystalline phase at 589 nm and along at least one principal axis may be at least approximately 1.5, at least approximately 1.6, at least approximately 1.7, at least approximately 1.8, at least approximately 1.9, at least approximately 2.0, at least approximately 2.1, at least approximately 2.2, at least approximately 2.3, at least approximately 2.4, at least approximately 2.5, or at least approximately 2.6, at least approximately 2.7, at least approximately 2.8, at least approximately 2.9, at least approximately 3, at least approximately 3.1, at least approximately 3.2, at least approximately 3.3, at least approximately 3.4, or at least approximately 3.5, including ranges between any of the foregoing values.

In some embodiments, the organic crystalline phase may be characterized by a birefringence (Dn), where n₁≠n₂≠n₃, n₁=n₂≠n₃, n₁≠n₂=n₃, or n₁=n₃≠n₂, of 0.001 to 1.5, e.g., at least approximately 0.001, at least approximately 0.002, at least approximately 0.005, at least approximately 0.01, at least approximately 0.02, at least approximately 0.05, at least approximately 0.1, at least approximately 0.2, at least approximately 0.3, at least approximately 0.4, at least approximately 0.5, or at least approximately 1, including ranges between any of the foregoing values. In some embodiments, a birefringent organic crystalline phase may be characterized by a birefringence of less than approximately 0.05, e.g., less than approximately 0.05, less than approximately 0.02, less than approximately 0.01, less than approximately 0.005, less than approximately 0.002, or less than approximately 0.001, including ranges between any of the foregoing values.

An illustrative method includes forming a green body of particles of an organic solid crystal material and heating the green body to sintering temperature effective to densify the particles and form an optical element. In some embodiments, the sintering temperature is less than a melting temperature of the organic solid crystal material.

The green body may include a sintering aid and the act of sintering may include applying pressure to the green body. Sintering aids are additives introduced during the consolidation of organic solid crystal (OSC) particles to promote densification and improve the microstructural integrity of the final element. These materials can lower the sintering temperature, enhance particle bonding, and reduce porosity, resulting in substrates or optical components with improved transparency and mechanical strength.

Sintering aids may include small organic molecules, low molecular weight polymers, inorganic compounds, metal salts, or surfactants, selected based on their compatibility with the OSC material and the desired properties of the consolidated body. The use of sintering aids enables more efficient processing and higher quality optical elements formed from OSC particles. An example sintering process includes spark plasma sintering.

In some embodiments, particles of an OSC material may be used in 3D printing to form optical elements or other parts. A sintering step may be used to densify the printed structure. Sintering may be effective to remove pores and increase transparency.

Organic solid crystal materials may be incorporated into passive and active optical waveguides, resonators, lasers, optical modulators, etc. Further example active optics include projectors and projection optics, ophthalmic high index lenses, eye-tracking, gradient- index optics, Pancharatnam-Berry phase (PBP) lenses, microlenses, pupil steering elements, optical computing, fiber optics, rewritable optical data storage, all-optical logic gates, multi-wavelength optical data processing, optical transistors, etc. According to further embodiments, organic solid crystal materials may be incorporated into passive optics, such as windows, optical prisms, waveguides, reflective polarizers, refractive/diffractive lenses, and the like. Related optical elements for passive optics may include polarization selective gratings, Fresnel lenses, microlenses, geometric lenses, PBP lenses, optical light pipes, optical diffusers, beamsplitters, and multilayer thin films.

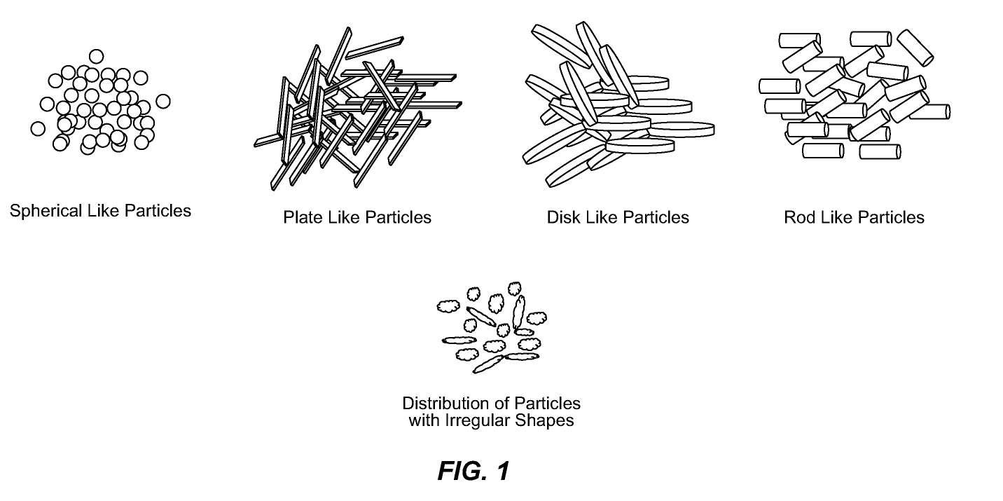

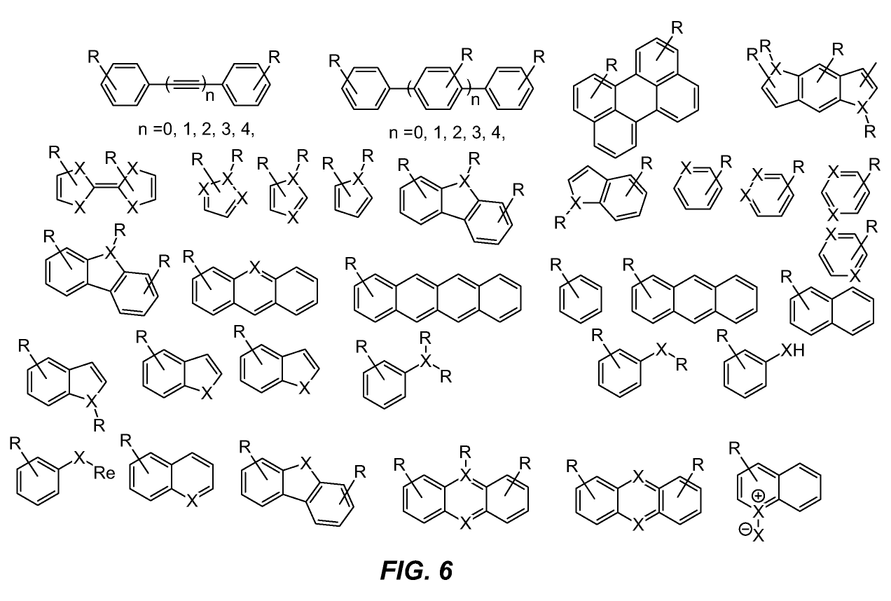

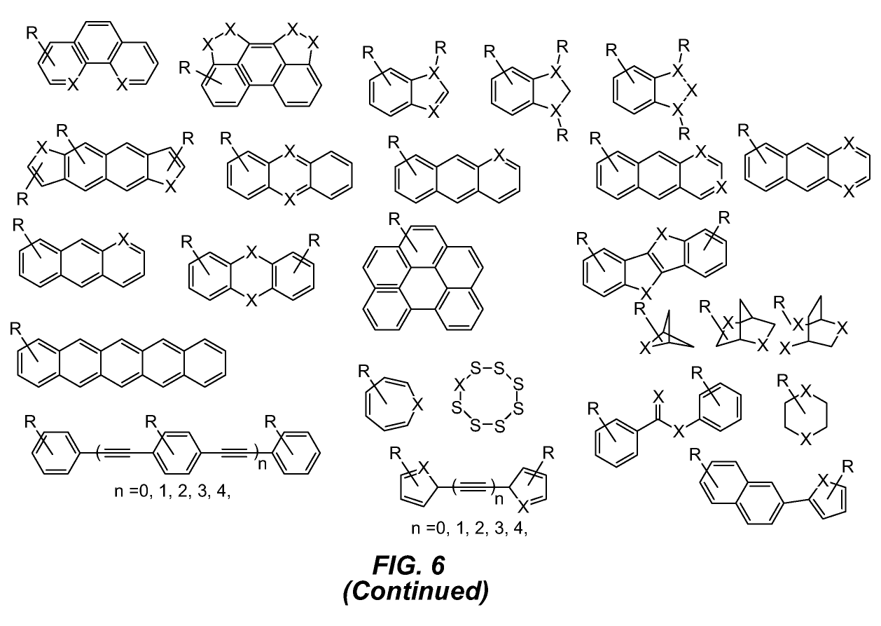

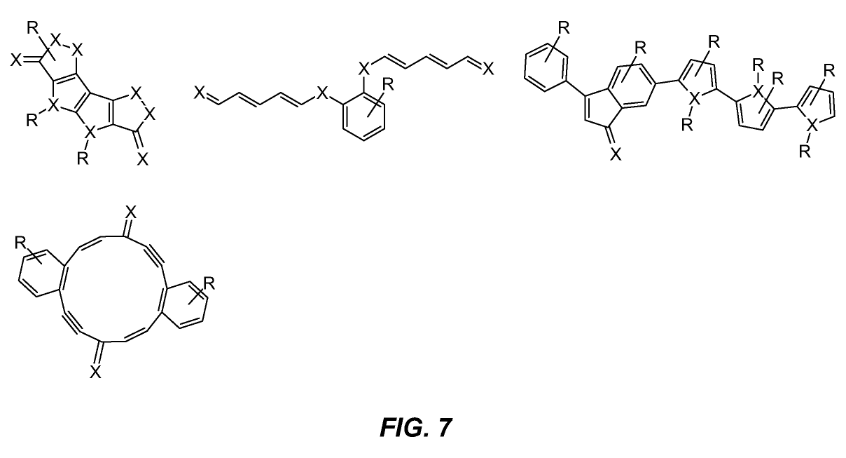

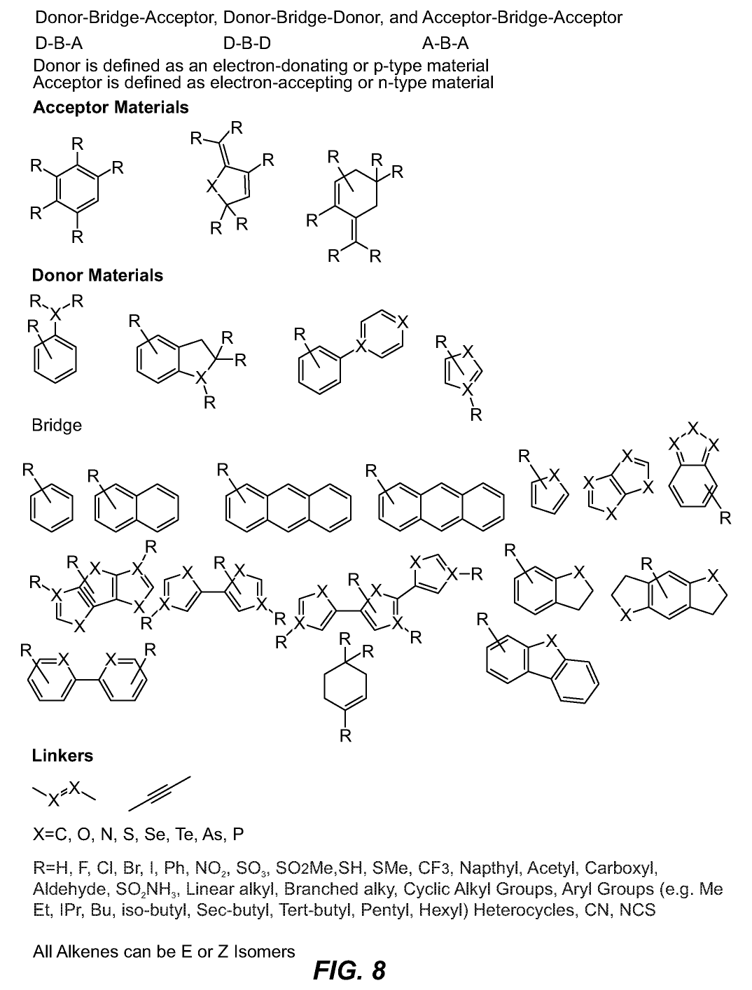

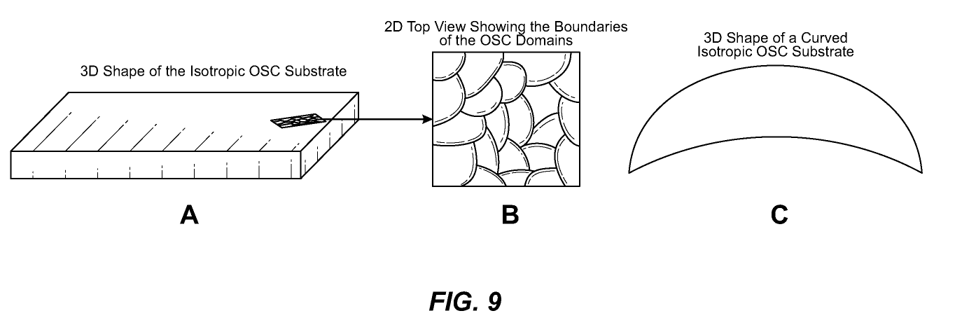

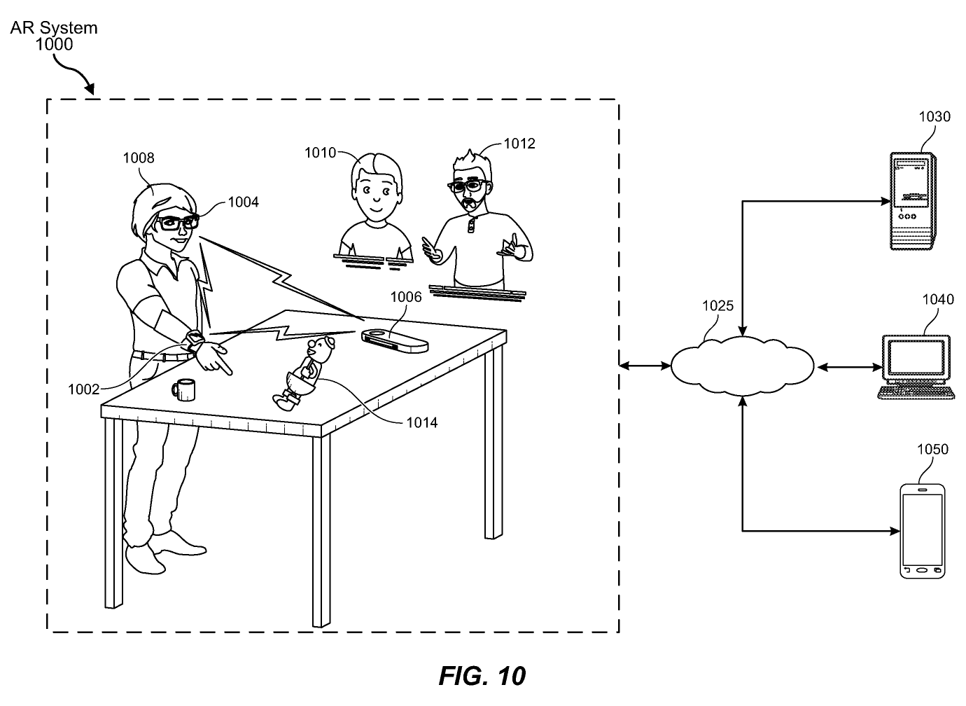

The following will provide, with reference to FIGS. 1-18, detailed descriptions of organic solid crystal (OSC) materials having a particulate morphology and densified structures formed from same. The discussion associated with FIGS. 1-8 includes a description of example methods for forming OSC particles, and the discussion associated with FIG. 9 includes a description of example densified structures formed from such particles. The discussion associated with FIGS. 10-18 relates to exemplary display devices that may include an OSC material as disclosed herein.

According to various embodiments, an OSC particle size may range from approximately 10 nm to approximately 10 micrometers, e.g., 10, 20, 50, 100, 200, 500, 1000, 2000, 5000, or 10000 nm, including ranges between any of the foregoing values. In addition, as illustrated in FIG. 1, the shape of an OSC particle or powder is not especially limited and example OSC particles may be spherical particles, plate like particles, disk like particles, rod like particles, or a distribution of particles having irregular shapes. An example batch of OSC particles may include a mixture of different regular and irregular shapes and sizes.

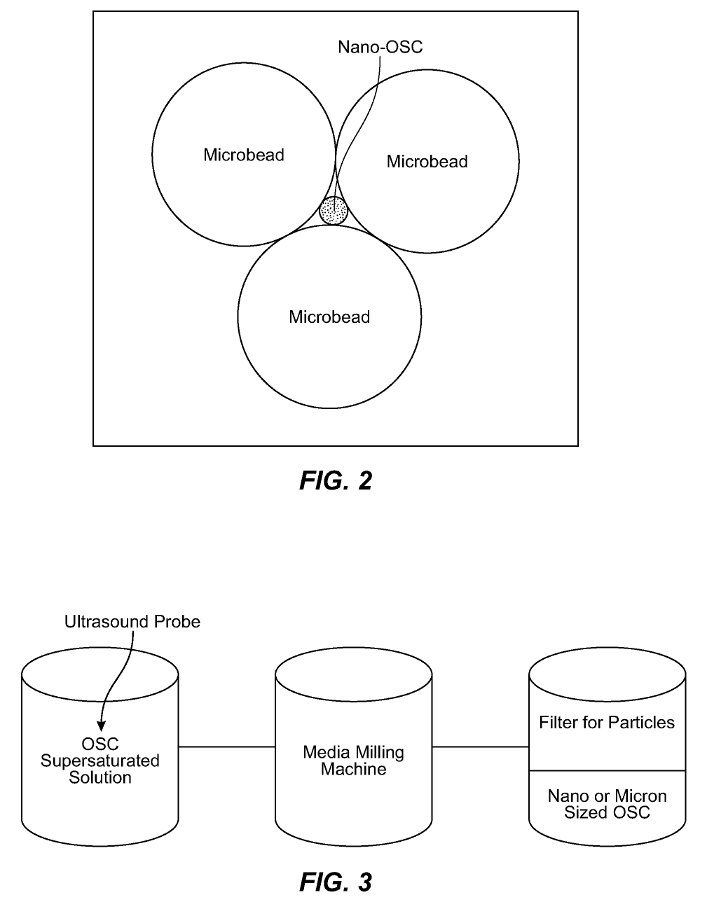

Referring to FIG. 2, illustrated is a process for forming nanoscale organic solid crystal (OSC) particles utilizing microbead-based milling techniques. In some embodiments, OSC bulk material is subjected to mechanical comminution in the presence of microbeads, which serve as the milling media. The OSC bulk material, which may be in the form of larger granules, aggregates, or bulk crystalline material, may be loaded into a milling chamber along with microbeads of a selected size and composition. The microbeads may be composed of materials such as zirconia, alumina, glass, or polymer, and their size may range from approximately 10 micrometers to 50 millimeters, although both smaller and larger bead sizes are contemplated depending on the desired particle size distribution and milling efficiency.

During the milling process, the chamber may be agitated, rotated, or vibrated to induce collisions between the microbeads and the OSC bulk material. These collisions impart mechanical energy to the bulk material, resulting in fracture, attrition, and size reduction of the OSC particles. The process parameters, including bead size, bead material, milling speed, duration, and the ratio of beads to precursor, may be selected to achieve a target mean particle size and a desired particle size distribution.

In some embodiments, the milling may be performed under dry conditions, where the OSC bulk material and microbeads are the only components present in the chamber. Alternatively, wet milling may be employed, wherein an organic solvent or a mixture of solvents is added to the chamber to facilitate dispersion of the OSC particles and to minimize agglomeration during milling. The solvent is selected such that it does not dissolve the OSC bulk material, thereby preserving the crystalline integrity of the resulting particles.

Following the milling step, the OSC particles may be separated from the microbeads using sieving, filtration, or sedimentation techniques. The resulting OSC particles may exhibit a nanoscale size, for example, having a mean diameter in the range of approximately 10 nanometers to 1 micrometer, and may possess regular or irregular shapes depending on the milling conditions and the nature of the precursor material. The process may be further refined to produce OSC particles with a narrow size distribution, which may be advantageous for subsequent densification, sintering, or incorporation into optical elements.

Microbead-based milling as depicted in FIG. 2 offers several advantages for the production of OSC particles. The technique enables scalable and controllable size reduction, is compatible with a wide range of organic crystalline materials and can be adapted for batch or continuous processing. Additionally, the use of microbeads allows for fine tuning of the particle morphology and surface characteristics, which may influence the optical, mechanical, and processing properties of the OSC particles. The resulting nanoscale OSC particles are suitable for use in the fabrication of high refractive index substrates, optical elements, and other devices as described throughout this disclosure.

Referring to FIG. 3, the schematic illustrates a solution-based process for producing organic solid crystal (OSC) particles with controlled size and morphology. The process begins by dissolving one or more organic compounds in a suitable solvent to form a homogeneous solution. The choice of solvent is determined by the solubility and compatibility with the organic compound, and may include water, toluene, dimethylformamide (DMF), tetrahydrofuran (THF), methanol, acetone, xylene, pyridine, dichlorobenzene, acetic acid, hexane, cyclohexane, chloroform, N-methyl-2-pyrrolidone (NMP), or other solvents appropriate for the selected compound.

Crystallization of OSC particles may be initiated by manipulating the solution conditions to induce nucleation and growth. This may be accomplished by cooling a supersaturated solution, evaporating the solvent, or introducing an antisolvent to trigger the formation of solid crystals. In certain embodiments, the solution may be exposed to ultrasonic waves at frequencies greater than 5 kHz, which promote nucleation and allow for control over the growth rate and final particle size. The temperature and residence time during this step may be selected based on the properties of the organic compound, enabling precise adjustment of the resulting particle dimensions.

Once the OSC particles have formed, the process may include a milling step to further refine the particle size distribution. The OSC particles, which may initially exhibit a broad range of sizes and shapes, are subjected to mechanical comminution using a milling machine. This milling step may utilize microbeads or other suitable media to fracture and reduce the size of the OSC particles, resulting in a more uniform and narrow particle size distribution. The milling parameters, such as media size, milling speed, and duration, are selected to achieve the desired mean particle size and morphology while preserving the crystalline integrity of the OSC material.

After milling, a filtering step may be employed to separate particles by size and remove any oversized or agglomerated material. The filtration may produce a batch of OSC particles with a narrow size distribution, which may be advantageous for subsequent processing steps such as densification, sintering, or incorporation into optical elements.

The combination of solution-based nucleation, ultrasonic induction, milling, and filtration as depicted in FIG. 3 enables scalable production of OSC particles with tunable size and morphology. The resulting OSC particles are suitable for use in high refractive index substrates, optical elements, and advanced optoelectronic devices.

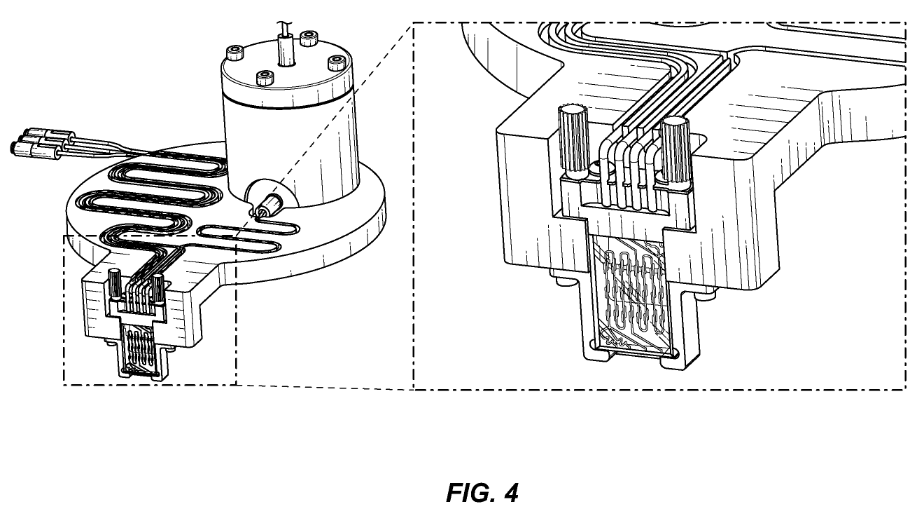

Turning to FIG. 4, shown is a microfluidic device configured for the manufacturing of organic solid crystal (OSC) particles. The microfluidic apparatus may be designed to precisely control the formation of OSC particles by manipulating solution flow, temperature, and droplet size within micro-scale channels. The device typically includes a network of microchannels fabricated from materials such as glass, silicon, or polymers, which are chemically compatible with the OSC solution and any processing solvents.

The process begins with the introduction of a precursor solution containing one or more organic compounds dissolved in a suitable solvent. This solution is injected into the microfluidic channels, where it may be combined with an immiscible carrier fluid to form an emulsion of discrete droplets. The size of these droplets may be determined by the flow rates of the precursor solution and carrier fluid, as well as the geometry of the microchannels. By adjusting these parameters, the device enables precise control over the initial droplet size, which directly influences the final size of the OSC particles.

A co-integrated heating stage is incorporated into the microfluidic device to regulate the temperature of the precursor solution within the channels. Temperature control may influence nucleation and crystal growth at desired rates. For example, the heating stage may be used to maintain the solution at a temperature that promotes supersaturation, followed by controlled cooling to trigger nucleation. The residence time of the solution within the heated region can be adjusted to optimize crystal growth and particle morphology.

As the emulsion flows through the microfluidic channels, nucleation and growth of OSC particles occur within the confined droplets. The microfluidic environment allows for uniform thermal and chemical conditions, resulting in highly consistent particle size and morphology across batches. Once crystallization is complete, the OSC particles are collected from the output of the device. Additional steps such as drying, washing, or filtering may be performed to isolate the OSC particles and remove any residual solvents or carrier fluids.

The microfluidic approach depicted in FIG. 4 offers several advantages for the synthesis of OSC particles. It enables continuous, scalable production with fine control over particle size distribution and morphology. The ability to precisely regulate temperature, flow rate, and droplet formation within the device allows for the reproducible manufacture of OSC particles tailored for specific optical and electronic applications. This method is compatible with a wide range of organic compounds and solvents, making it suitable for the development of high refractive index materials, optical substrates, and advanced optoelectronic components.

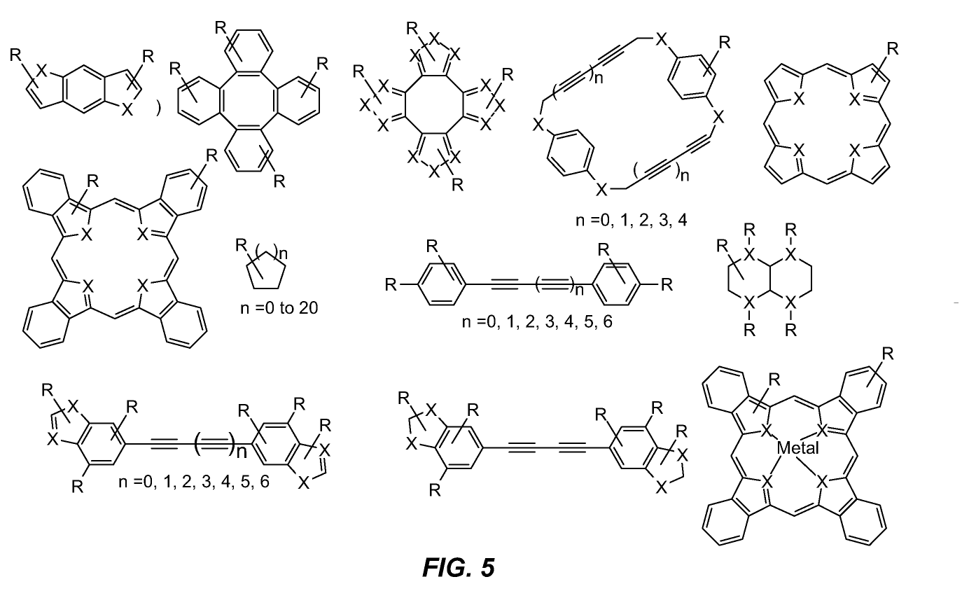

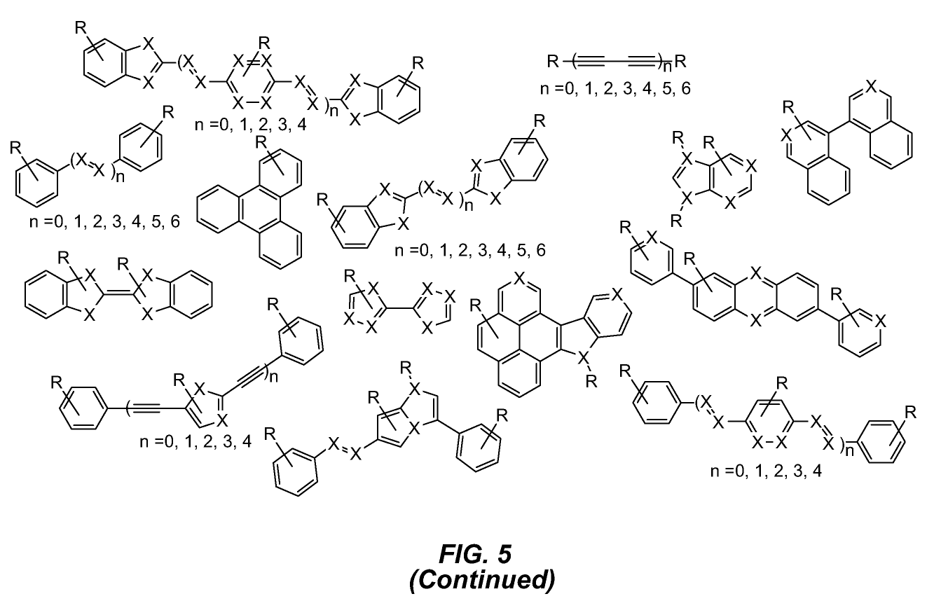

OSC particles may be formed from a variety of molecular precursors. Example precursor materials are illustrated in FIGS. 5-8. To form a precursor solution, one or more molecular precursors may be dissolved in a suitable solvent. Example solvents include water, toluene, dimethylformamide (DMF), tetrahydrofuran (THF), methanol, acetone, xylene, pyridine, dichlorobenzene, acetic acid, hexane, cyclohexane, chloroform, N-methyl-2-pyrrolidone (NMP), and the like.

Referring to FIG. 9, shown are example high refractive index organic solid polycrystalline substrates formed from densified OSC particles. FIG. 9A presents an isometric view of an optically isotropic organic solid polycrystalline substrate, which is composed of sintered OSC particles consolidated into a monolithic body. The substrate may exhibit uniform optical properties throughout its volume, with minimal birefringence and high transparency. Such isotropic substrates are advantageous for applications requiring consistent refractive index and optical clarity, such as lenses, windows, and optical waveguides.

FIG. 9B provides a corresponding top-down plan view, revealing the presence of individual OSC domains within the polycrystalline substrate. These domains represent regions of crystalline alignment or grain boundaries resulting from the sintering and densification process. The distribution, size, and orientation of the domains can be tailored by controlling the initial particle size, sintering temperature, pressure, and the use of sintering aids. A narrow grain size distribution and uniform domain structure contribute to reduced optical scattering, low haze, and improved mechanical integrity.

FIG. 9C depicts an optically isotropic organic solid polycrystalline substrate having a non-planar surface. The non-planar geometry may be introduced during molding or post-processing stages, enabling the fabrication of optical elements with complex surface profiles, such as curved lenses, prisms, or freeform optics. The ability to produce substrates with non-planar surfaces expands the range of potential applications, including advanced imaging systems, augmented reality displays, and custom optical components.

The substrates illustrated in FIG. 9 may be characterized by a density in the range of 1.1 to 2 g/cm³ and an average refractive index between 1.5 and 3.5, as achieved through the sintering of OSC particles. The sintering process may be performed at temperatures below the melting point of the organic solid crystal material, preserving the crystalline phase and minimizing thermal degradation. The resulting polycrystalline body may exhibit low bulk haze (less than 10%) and a low yellowness index (|b*| less than 0.5 per 50 μm), ensuring high optical quality and color fidelity.

In some embodiments, the sintered substrate may possess a visible spectrum transmittance of at least approximately 80% or a near infrared spectrum transmittance of at least approximately 60%. The average grain size within the substrate may range from 20 nanometers to 1 micrometer, which further contributes to the optical performance and mechanical robustness of the material. The ability to engineer the substrate’s surface—planar or non-planar—and its internal microstructure enables the design of optical elements tailored for specific device architectures and performance requirements.

The substrates shown in FIG. 9 exemplify the integration of OSC particle technology into high-performance optical components suitable for use in advanced optoelectronic devices, wearable systems, and artificial reality platforms.

Organic solid crystal (OSC) particles are described, each with a crystalline structure based on organic compounds such as anthracene, phenanthrene, pyrene, corannulene, fluorene, and biphenyl. Particle sizes range from about 10 nanometers to 10 millimeters, and refractive indices range from 1.5 to 3.5. Methods for producing OSC particles include solution-based crystallization, ultrasonic nucleation, microbead milling, and microfluidic synthesis, allowing precise control over particle size and morphology.

Elements such as substrates and optical components may be formed from consolidated OSC particles, resulting in monolithic bodies with high transparency, low haze, and tunable birefringence. These elements may be planar or non-planar and are suitable for optoelectronic devices, wearable systems, and artificial reality platforms, providing lightweight, customizable, and high-performance alternatives to comparative optical materials.

### Example Embodiments

Example 1: An organic solid crystal material has a particulate solid body having a crystalline structure formed from an organic compound, where a particle size of the particulate solid body ranges from 10 nm to 10 mm; and a refractive index of the particular body range from 1.5 to 3.5 along at least one dimension of the particulate solid body.

Example 2: The organic solid crystal material of Example 1, where the particulate solid body has a shape selected from spherical, platelet, disk, and rod.

Example 3: The organic solid crystal material of any of Examples 1 and 2, where the particulate solid body is optically anisotropic.

Example 4: The organic solid crystal material of any of Examples 1-3, where the particulate solid body has a major length and the refractive index is greatest along the major length.

Example 5: The organic solid crystal material of any of Examples 1-4, where the crystalline structure has a density ranging from approximately 1.1 to approximately 2 g/cm³.

Example 6: The organic solid crystal material of any of Examples 1-5, where the organic compound includes at least one of anthracene, phenanthrene, pyrene, corannulene, fluorene, and biphenyl.

Example 7: An article includes a solid body having a polycrystalline structure formed from an organic compound, where the solid body has a density of 1.1 to 2 g/cm³, and an average refractive index of 1.5 to 3.5.

Example 8: The article of Example 7, where the solid body includes a non-planar surface.

Example 9: The article of any of Examples 7 and 8, where the solid body includes a planar surface.

Example 10: The article of any of Examples 7-9, where the solid body is optically isotropic.

Example 11: The article of any of Examples 7-9, where the solid body is optically anisotropic.

Example 12 The article of any of Examples 7-11, where the solid body has a visible spectrum transmittance of at least 80% and a near infrared spectrum transmittance of at least 60%.

Example 13: The article of any of Examples 7-12, where the solid body exhibits less than 10% bulk haze and a yellowness index |b*| less than 0.5 per 50 μm.

Example 14: The article of any of Examples 7-13, where the solid body includes sintered particles each having a crystalline structure and formed from an organic compound.

Example 15: The article of any of Examples 7-14, where the solid body has an average grain size of 20 nanometers to 1 micrometer.

Example 16: A method includes forming a green body from particles of an organic solid crystal material and heating the green body to a sintering temperature effective to densify the particles and form an optical element.

Example 17: The method of Example 16, where the green body includes a sintering aid.

Example 18: The method of Example 16, where the green body is free of a sintering aid.

Example 19: The method of any of Examples 16-18, where heating the green body includes spark plasma sintering.

Example 20: The method of any of Examples 16-19, where the sintering temperature is less than a melting temperature of the organic solid crystal material.

Embodiments of the present disclosure may include or be implemented in conjunction with various types of Artificial-Reality (AR) systems. AR may be any superimposed functionality and/or sensory-detectable content presented by an artificial-reality system within a user’s physical surroundings. In other words, AR is a form of reality that has been adjusted in some manner before presentation to a user. AR can include and/or represent virtual reality (VR), augmented reality, mixed AR (MAR), or some combination and/or variation of these types of realities. Similarly, AR environments may include VR environments (including non-immersive, semi-immersive, and fully immersive VR environments), augmented-reality environments (including marker-based augmented-reality environments, markerless augmented-reality environments, location-based augmented-reality environments, and projection-based augmented-reality environments), hybrid-reality environments, and/or any other type or form of mixed- or alternative-reality environments.

AR content may include completely computer-generated content or computer-generated content combined with captured (e.g., real-world) content. Such AR content may include video, audio, haptic feedback, or some combination thereof, any of which may be presented in a single channel or in multiple channels (such as stereo video that produces a three-dimensional (3D) effect to the viewer). Additionally, in some embodiments, AR may also be associated with applications, products, accessories, services, or some combination thereof, that are used to, for example, create content in an artificial reality and/or are otherwise used in (e.g., to perform activities in) an artificial reality.

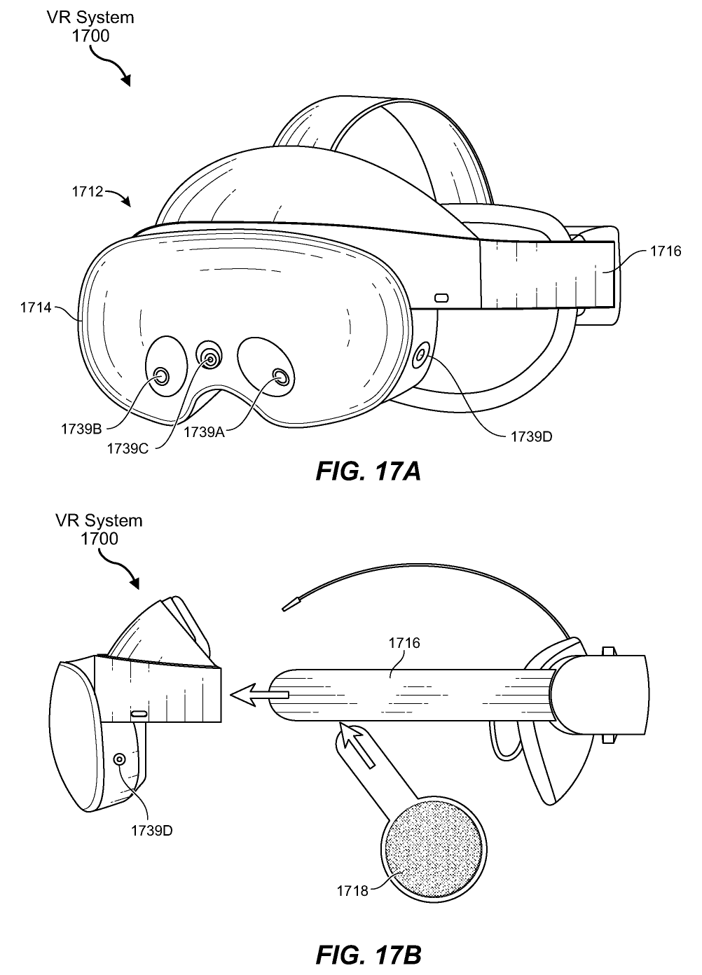

AR systems may be implemented in a variety of different form factors and configurations. Some AR systems may be designed to work without near-eye displays (NEDs). Other AR systems may include a NED that also provides visibility into the real world (such as, e.g., VR system 1700 in FIGS. 17A and 17B). While some AR devices may be self-contained systems, other AR devices may communicate and/or coordinate with external devices to provide an AR experience to a user. Examples of such external devices include handheld controllers, mobile devices, desktop computers, devices worn by a user, devices worn by one or more other users, and/or any other suitable external system.

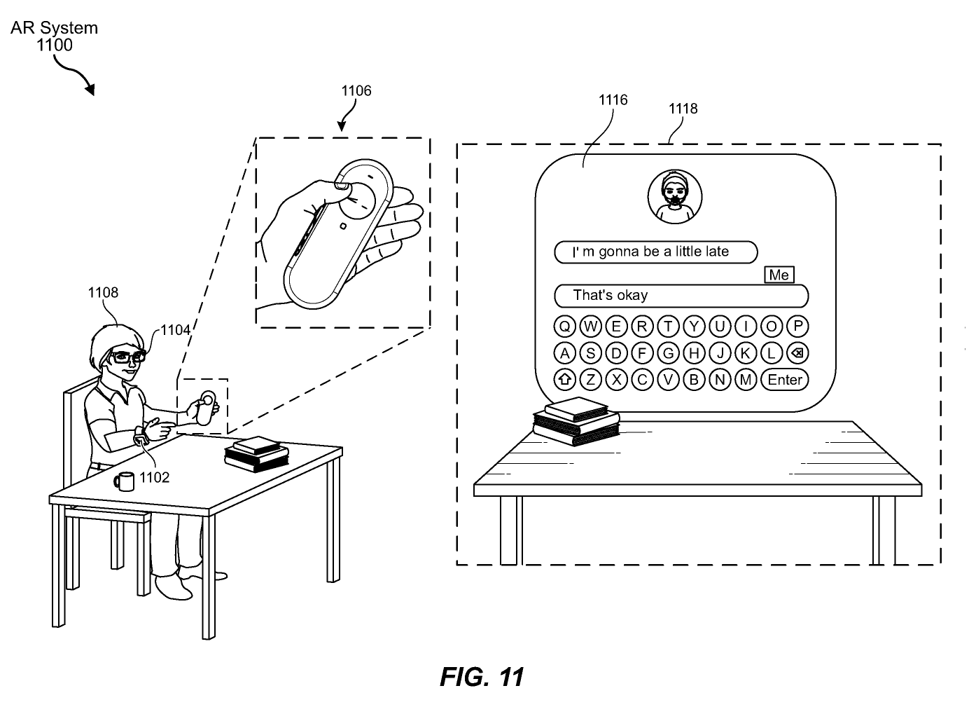

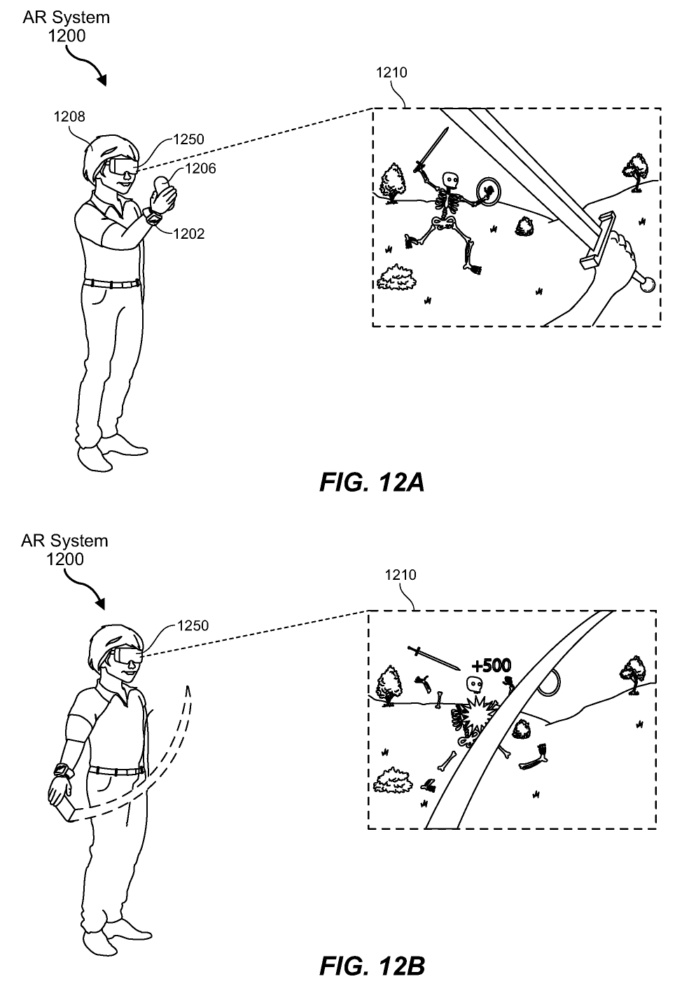

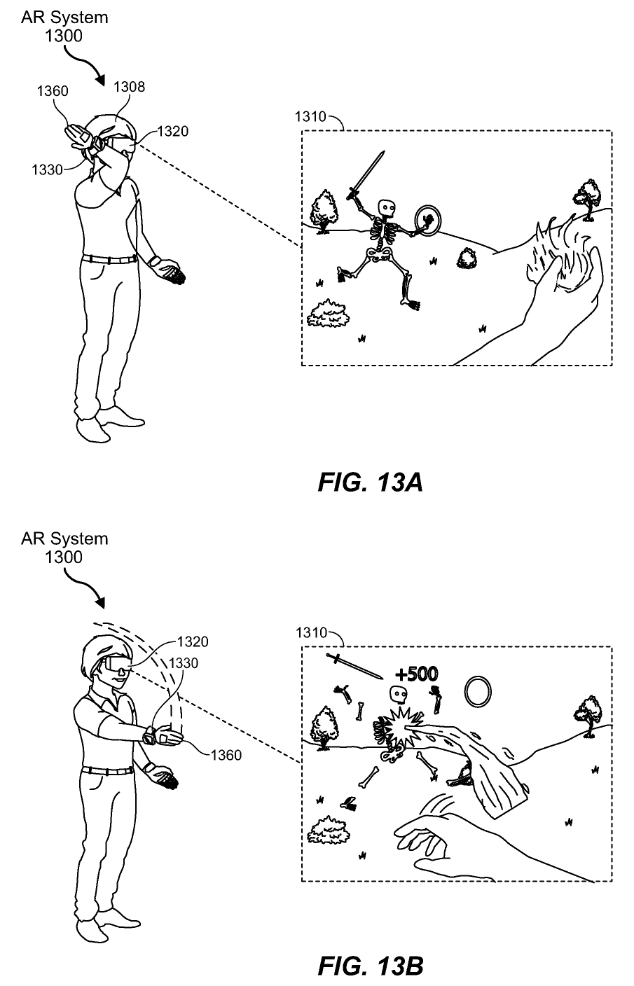

FIGS. 10-13B illustrate example artificial-reality (AR) systems in accordance with some embodiments. FIG. 10 shows a first AR system 1000 and first example user interactions using a wrist-wearable device 1002, a head-wearable device (e.g., AR system 1600), and/or a handheld intermediary processing device (HIPD) 1006. FIG. 11 shows a second AR system 1100 and second example user interactions using a wrist-wearable device 1102, AR glasses 1104, and/or an HIPD 1106. FIGS. 12A and 12B show a third AR system 1200 and third example user 1208 interactions using a wrist-wearable device 1202, a head-wearable device (e.g., VR headset 1250), and/or an HIPD 1206. FIGS. 13A and 13B show a fourth AR system 1300 and fourth example user 1308 interactions using a wrist-wearable device 1330, VR headset 1320, and/or a haptic device 1360 (e.g., wearable gloves).

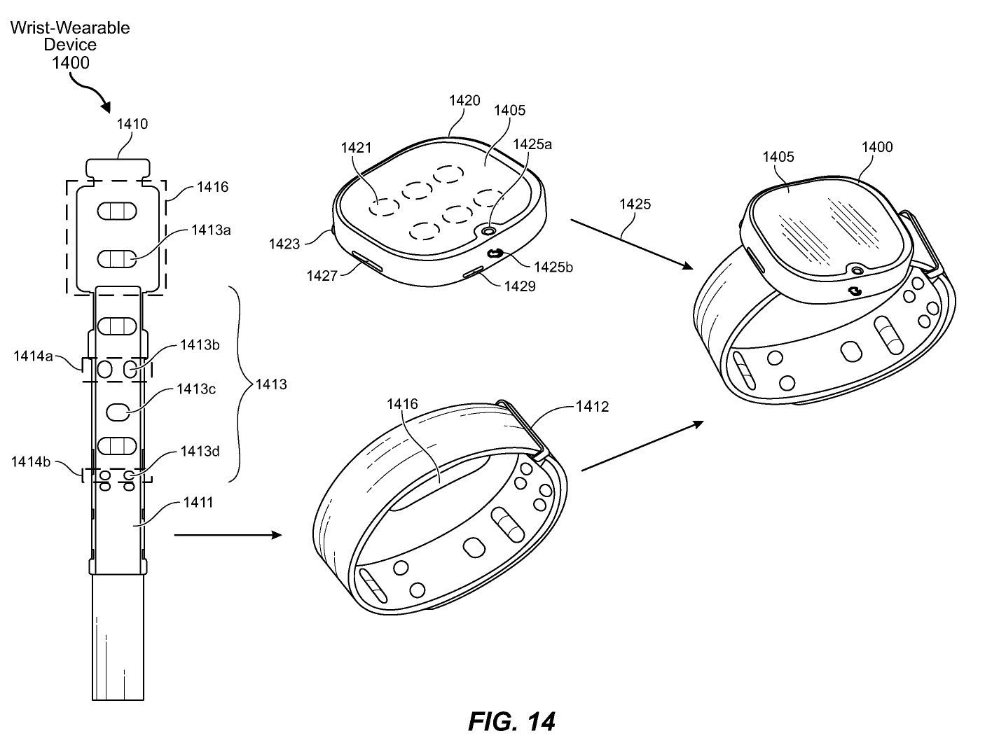

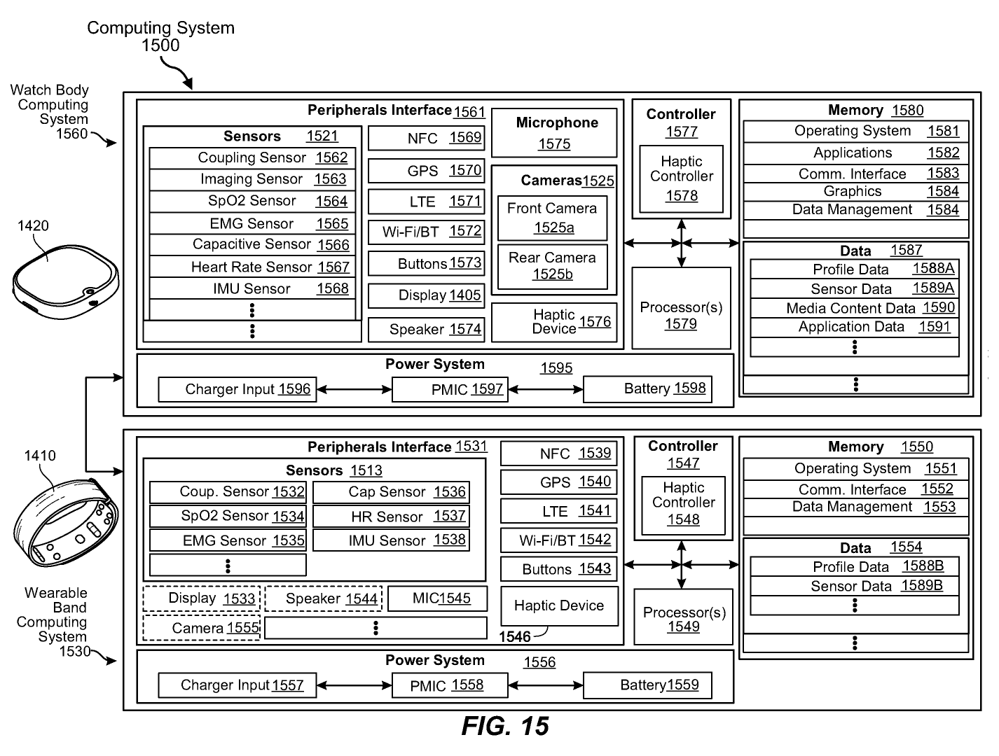

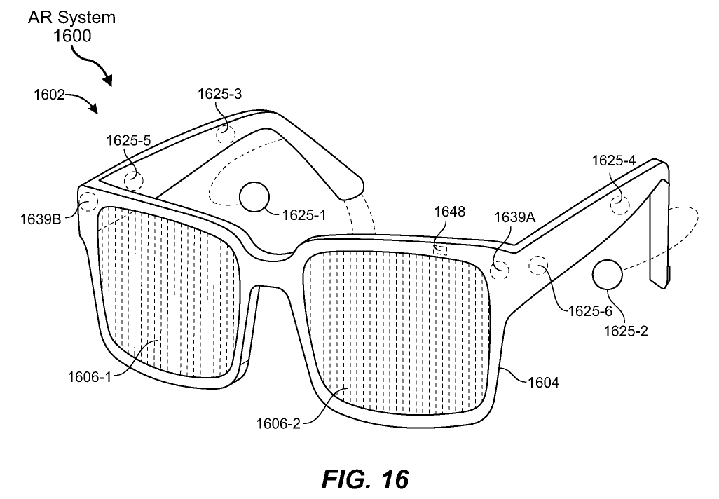

A wrist-wearable device 1400, which can be used for wrist-wearable device 1002, 1102, 1202, 1330, and one or more of its components, are described below in reference to FIGS. 14 and 15; AR system 1600 and VR system 1700, which can respectively be used for AR glasses 1004, 1104 or VR headset 1250, 1320, and their one or more components are described below in reference to FIGS. 16-18.

Referring to FIG. 10, wrist-wearable device 1002, AR glasses 1004, and/or HIPD 1006 can communicatively couple via a network 1025 (e.g., cellular, near field, Wi-Fi, personal area network, wireless LAN, etc.). Additionally, wrist-wearable device 1002, AR glasses 1004, and/or HIPD 1006 can also communicatively couple with one or more servers 1030, computers 1040 (e.g., laptops, computers, etc.), mobile devices 1050 (e.g., smartphones, tablets, etc.), and/or other electronic devices via network 1025 (e.g., cellular, near field, Wi-Fi, personal area network, wireless LAN, etc.).

In FIG. 10, a user 1008 is shown wearing wrist-wearable device 1002 and AR glasses 1004 and having HIPD 1006 on their desk. The wrist-wearable device 1002, AR glasses 1004, and HIPD 1006 facilitate user interaction with an AR environment. In particular, as shown by first AR system 1000, wrist-wearable device 1002, AR glasses 1004, and/or HIPD 1006 cause presentation of one or more avatars 1010, digital representations of contacts 1012, and virtual objects 1014. As discussed below, user 1008 can interact with one or more avatars 1010, digital representations of contacts 1012, and virtual objects 1014 via wrist-wearable device 1002, AR glasses 1004, and/or HIPD 1006.

User 1008 can use any of wrist-wearable device 1002, AR glasses 1004, and/or HIPD 1006 to provide user inputs. For example, user 1008 can perform one or more hand gestures that are detected by wrist-wearable device 1002 (e.g., using one or more EMG sensors and/or IMUs, described below in reference to FIGS. 14 and 15) and/or AR glasses 1004 (e.g., using one or more image sensor or camera, described below in reference to FIGS. 16-10) to provide a user input. Alternatively, or additionally, user 1008 can provide a user input via one or more touch surfaces of wrist-wearable device 1002, AR glasses 1004, HIPD 1006, and/or voice commands captured by a microphone of wrist-wearable device 1002, AR glasses 1004, and/or HIPD 1006. In some embodiments, wrist-wearable device 1002, AR glasses 1004, and/or HIPD 1006 include a digital assistant to help user 1008 in providing a user input (e.g., completing a sequence of operations, suggesting different operations or commands, providing reminders, confirming a command, etc.). In some embodiments, user 1008 can provide a user input via one or more facial gestures and/or facial expressions. For example, cameras of wrist-wearable device 1002, AR glasses 1004, and/or HIPD 1006 can track eyes of user 1008 for navigating a user interface.

Wrist-wearable device 1002, AR glasses 1004, and/or HIPD 1006 can operate alone or in conjunction to allow user 1008 to interact with the AR environment. In some embodiments, HIPD 1006 is configured to operate as a central hub or control center for the wrist-wearable device 1002, AR glasses 1004, and/or another communicatively coupled device. For example, user 1008 can provide an input to interact with the AR environment at any of wrist-wearable device 1002, AR glasses 1004, and/or HIPD 1006, and HIPD 1006 can identify one or more back-end and front-end tasks to cause the performance of the requested interaction and distribute instructions to cause the performance of the one or more back-end and front-end tasks at wrist-wearable device 1002, AR glasses 1004, and/or HIPD 1006. In some embodiments, a back-end task is a background processing task that is not perceptible by the user (e.g., rendering content, decompression, compression, etc.), and a front-end task is a user-facing task that is perceptible to the user (e.g., presenting information to the user, providing feedback to the user, etc.). As described below, HIPD 1006 can perform the back-end tasks and provide wrist-wearable device 1002 and/or AR glasses 1004 operational data corresponding to the performed back-end tasks such that wrist-wearable device 1002 and/or AR glasses 1004 can perform the front-end tasks. In this way, HIPD 1006, which has more computational resources and greater thermal headroom than wrist-wearable device 1002 and/or AR glasses 1004, performs computationally intensive tasks and reduces the computer resource utilization and/or power usage of wrist-wearable device 1002 and/or AR glasses 1004.

In the example shown by first AR system 1000, HIPD 1006 identifies one or more back-end tasks and front-end tasks associated with a user request to initiate an AR video call with one or more other users (represented by avatar 1010 and the digital representation of contact 1012) and distributes instructions to cause the performance of the one or more back-end tasks and front-end tasks. In particular, HIPD 1006 performs back-end tasks for processing and/or rendering image data (and other data) associated with the AR video call and provides operational data associated with the performed back-end tasks to AR glasses 1004 such that the AR glasses 1004 perform front-end tasks for presenting the AR video call (e.g., presenting avatar 1010 and digital representation of contact 1012).

In some embodiments, HIPD 1006 can operate as a focal or anchor point for causing the presentation of information. This allows user 1008 to be generally aware of where information is presented. For example, as shown in first AR system 1000, avatar 1010 and the digital representation of contact 1012 are presented above HIPD 1006. In particular, HIPD 1006 and AR glasses 1004 operate in conjunction to determine a location for presenting avatar 1010 and the digital representation of contact 1012. In some embodiments, information can be presented a predetermined distance from HIPD 1006 (e.g., within 5 meters). For example, as shown in first AR system 1000, virtual object 1014 is presented on the desk some distance from HIPD 1006. Similar to the above example, HIPD 1006 and AR glasses 1004 can operate in conjunction to determine a location for presenting virtual object 1014. Alternatively, in some embodiments, presentation of information is not bound by HIPD 1006. More specifically, avatar 1010, digital representation of contact 1012, and virtual object 1014 do not have to be presented within a predetermined distance of HIPD 1006.

User inputs provided at wrist-wearable device 1002, AR glasses 1004, and/or HIPD 1006 are coordinated such that the user can use any device to initiate, continue, and/or complete an operation. For example, user 1008 can provide a user input to AR glasses 1004 to cause AR glasses 1004 to present virtual object 1014 and, while virtual object 1014 is presented by AR glasses 1004, user 1008 can provide one or more hand gestures via wrist-wearable device 1002 to interact and/or manipulate virtual object 1014.

FIG. 11 shows a user 1108 wearing a wrist-wearable device 1102 and AR glasses 1104, and holding an HIPD 1106. In second AR system 1100, the wrist-wearable device 1102, AR glasses 1104, and/or HIPD 1106 are used to receive and/or provide one or more messages to a contact of user 1108. In particular, wrist-wearable device 1102, AR glasses 1104, and/or HIPD 1106 detect and coordinate one or more user inputs to initiate a messaging application and prepare a response to a received message via the messaging application.

In some embodiments, user 1108 initiates, via a user input, an application on wrist-wearable device 1102, AR glasses 1104, and/or HIPD 1106 that causes the application to initiate on at least one device. For example, in second AR system 1100, user 1108 performs a hand gesture associated with a command for initiating a messaging application (represented by messaging user interface 1116), wrist-wearable device 1102 detects the hand gesture and, based on a determination that user 1108 is wearing AR glasses 1104, causes AR glasses 1104 to present a messaging user interface 1116 of the messaging application. AR glasses 1104 can present messaging user interface 1116 to user 1108 via its display (e.g., as shown by a field of view 1118 of user 1108). In some embodiments, the application is initiated and executed on the device (e.g., wrist-wearable device 1102, AR glasses 1104, and/or HIPD 1106) that detects the user input to initiate the application, and the device provides another device operational data to cause the presentation of the messaging application. For example, wrist-wearable device 1102 can detect the user input to initiate a messaging application, initiate and run the messaging application, and provide operational data to AR glasses 1104 and/or HIPD 1106 to cause presentation of the messaging application. Alternatively, the application can be initiated and executed at a device other than the device that detected the user input. For example, wrist-wearable device 1102 can detect the hand gesture associated with initiating the messaging application and cause HIPD 1106 to run the messaging application and coordinate the presentation of the messaging application.

Further, user 1108 can provide a user input provided at wrist-wearable device 1102, AR glasses 1104, and/or HIPD 1106 to continue and/or complete an operation initiated at another device. For example, after initiating the messaging application via wrist-wearable device 1102 and while AR glasses 1104 present messaging user interface 1116, user 1108 can provide an input at HIPD 1106 to prepare a response (e.g., shown by the swipe gesture performed on HIPD 1106). Gestures performed by user 1108 on HIPD 1106 can be provided and/or displayed on another device. For example, a swipe gestured performed on HIPD 1106 is displayed on a virtual keyboard of messaging user interface 1116 displayed by AR glasses 1104.

In some embodiments, wrist-wearable device 1102, AR glasses 1104, HIPD 1106, and/or any other communicatively coupled device can present one or more notifications to user 1108. The notification can be an indication of a new message, an incoming call, an application update, a status update, etc. User 1108 can select the notification via wrist-wearable device 1102, AR glasses 1104, and/or HIPD 1106 and can cause presentation of an application or operation associated with the notification on at least one device. For example, user 1108 can receive a notification that a message was received at wrist-wearable device 1102, AR glasses 1104, HIPD 1106, and/or any other communicatively coupled device and can then provide a user input at wrist-wearable device 1102, AR glasses 1104, and/or HIPD 1106 to review the notification, and the device detecting the user input can cause an application associated with the notification to be initiated and/or presented at wrist-wearable device 1102, AR glasses 1104, and/or HIPD 1106.

While the above example describes coordinated inputs used to interact with a messaging application, user inputs can be coordinated to interact with any number of applications including, but not limited to, gaming applications, social media applications, camera applications, web-based applications, financial applications, etc. For example, AR glasses 1104 can present to user 1108 game application data, and HIPD 1106 can be used as a controller to provide inputs to the game. Similarly, user 1108 can use wrist-wearable device 1102 to initiate a camera of AR glasses 1104, and user 308 can use wrist-wearable device 1102, AR glasses 1104, and/or HIPD 1106 to manipulate the image capture (e.g., zoom in or out, apply filters, etc.) and capture image data.

Users may interact with the devices disclosed herein in a variety of ways. For example, as shown in FIGS. 12A and 12B, a user 1208 may interact with an AR system 1200 by donning a VR headset 1250 while holding HIPD 1206 and wearing wrist-wearable device 1202. In this example, AR system 1200 may enable a user to interact with a game 1210 by swiping their arm. One or more of VR headset 1250, HIPD 1206, and wrist-wearable device 1202 may detect this gesture and, in response, may display a sword strike in game 1210. Similarly, in FIGS. 13A and 13B, a user 1308 may interact with an AR system 1300 by donning a VR headset 1320 while wearing haptic device 1360 and wrist-wearable device 1330. In this example, AR system 1300 may enable a user to interact with a game 1310 by swiping their arm. One or more of VR headset 1320, haptic device 1360, and wrist-wearable device 1330 may detect this gesture and, in response, may display a spell being cast in game 1210.

Having discussed example AR systems, devices for interacting with such AR systems and other computing systems more generally will now be discussed in greater detail. Some explanations of devices and components that can be included in some or all of the example devices discussed below are explained herein for ease of reference. Certain types of the components described below may be more suitable for a particular set of devices, and less suitable for a different set of devices. But subsequent reference to the components explained here should be considered to be encompassed by the descriptions provided.

In some embodiments discussed below, example devices and systems, including electronic devices and systems, will be addressed. Such example devices and systems are not intended to be limiting, and one of skill in the art will understand that alternative devices and systems to the example devices and systems described herein may be used to perform the operations and construct the systems and devices that are described herein.

An electronic device may be a device that uses electrical energy to perform a specific function. An electronic device can be any physical object that contains electronic components such as transistors, resistors, capacitors, diodes, and integrated circuits. Examples of electronic devices include smartphones, laptops, digital cameras, televisions, gaming consoles, and music players, as well as the example electronic devices discussed herein. As described herein, an intermediary electronic device may be a device that sits between two other electronic devices and/or a subset of components of one or more electronic devices and facilitates communication, data processing, and/or data transfer between the respective electronic devices and/or electronic components.

An integrated circuit may be an electronic device made up of multiple interconnected electronic components such as transistors, resistors, and capacitors. These components may be etched onto a small piece of semiconductor material, such as silicon. Integrated circuits may include analog integrated circuits, digital integrated circuits, mixed signal integrated circuits, and/or any other suitable type or form of integrated circuit. Examples of integrated circuits include application-specific integrated circuits (ASICs), processing units, central processing units (CPUs), co-processors, and accelerators.

Analog integrated circuits, such as sensors, power management circuits, and operational amplifiers, may process continuous signals and perform analog functions such as amplification, active filtering, demodulation, and mixing. Examples of analog integrated circuits include linear integrated circuits and radio frequency circuits.

Digital integrated circuits, which may be referred to as logic integrated circuits, may include microprocessors, microcontrollers, memory chips, interfaces, power management circuits, programmable devices, and/or any other suitable type or form of integrated circuit. In some embodiments, examples of integrated circuits include central processing units (CPUs),

Processing units, such as CPUs, may be electronic components that are responsible for executing instructions and controlling the operation of an electronic device (e.g., a computer). There are various types of processors that may be used interchangeably, or may be specifically required, by embodiments described herein. For example, a processor may be: (i) a general processor designed to perform a wide range of tasks, such as running software applications, managing operating systems, and performing arithmetic and logical operations; (ii) a microcontroller designed for specific tasks such as controlling electronic devices, sensors, and motors; (iii) an accelerator, such as a graphics processing unit (GPU), designed to accelerate the creation and rendering of images, videos, and animations (e.g., virtual-reality animations, such as three-dimensional modeling); (iv) a field-programmable gate array (FPGA) that can be programmed and reconfigured after manufacturing and/or can be customized to perform specific tasks, such as signal processing, cryptography, and machine learning; and/or (v) a digital signal processor (DSP) designed to perform mathematical operations on signals such as audio, video, and radio waves. One or more processors of one or more electronic devices may be used in various embodiments described herein.

Memory generally refers to electronic components in a computer or electronic device that store data and instructions for the processor to access and manipulate. Examples of memory can include: (i) random access memory (RAM) configured to store data and instructions temporarily; (ii) read-only memory (ROM) configured to store data and instructions permanently (e.g., one or more portions of system firmware, and/or boot loaders) and/or semi-permanently; (iii) flash memory, which can be configured to store data in electronic devices (e.g., USB drives, memory cards, and/or solid-state drives (SSDs)); and/or (iv) cache memory configured to temporarily store frequently accessed data and instructions. Memory, as described herein, can store structured data (e.g., SQL databases, MongoDB databases, GraphQL data, JSON data, etc.). Other examples of data stored in memory can include (i) profile data, including user account data, user settings, and/or other user data stored by the user, (ii) sensor data detected and/or otherwise obtained by one or more sensors, (iii) media content data including stored image data, audio data, documents, and the like, (iv) application data, which can include data collected and/or otherwise obtained and stored during use of an application, and/or any other types of data described herein.

Controllers may be electronic components that manage and coordinate the operation of other components within an electronic device (e.g., controlling inputs, processing data, and/or generating outputs). Examples of controllers can include: (i) microcontrollers, including small, low-power controllers that are commonly used in embedded systems and Internet of Things (IoT) devices; (ii) programmable logic controllers (PLCs) that may be configured to be used in industrial automation systems to control and monitor manufacturing processes; (iii) system-on-a-chip (SoC) controllers that integrate multiple components such as processors, memory, I/O interfaces, and other peripherals into a single chip; and/or (iv) DSPs.

A power system of an electronic device may be configured to convert incoming electrical power into a form that can be used to operate the device. A power system can include various components, such as (i) a power source, which can be an alternating current (AC) adapter or a direct current (DC) adapter power supply, (ii) a charger input, which can be configured to use a wired and/or wireless connection (which may be part of a peripheral interface, such as a USB, micro-USB interface, near-field magnetic coupling, magnetic inductive and magnetic resonance charging, and/or radio frequency (RF) charging), (iii) a power-management integrated circuit, configured to distribute power to various components of the device and to ensure that the device operates within safe limits (e.g., regulating voltage, controlling current flow, and/or managing heat dissipation), and/or (iv) a battery configured to store power to provide usable power to components of one or more electronic devices.

Peripheral interfaces may be electronic components (e.g., of electronic devices) that allow electronic devices to communicate with other devices or peripherals and can provide the ability to input and output data and signals. Examples of peripheral interfaces can include (i) universal serial bus (USB) and/or micro-USB interfaces configured for connecting devices to an electronic device, (ii) Bluetooth interfaces configured to allow devices to communicate with each other, including Bluetooth low energy (BLE), (iii) near field communication (NFC) interfaces configured to be short-range wireless interfaces for operations such as access control, (iv) POGO pins, which may be small, spring-loaded pins configured to provide a charging interface, (v) wireless charging interfaces, (vi) GPS interfaces, (vii) Wi-Fi interfaces for providing a connection between a device and a wireless network, and/or (viii) sensor interfaces.

Sensors may be electronic components (e.g., in and/or otherwise in electronic communication with electronic devices, such as wearable devices) configured to detect physical and environmental changes and generate electrical signals. Examples of sensors can include (i) imaging sensors for collecting imaging data (e.g., including one or more cameras disposed on a respective electronic device), (ii) biopotential-signal sensors, (iii) inertial measurement units (e.g., IMUs) for detecting, for example, angular rate, force, magnetic field, and/or changes in acceleration, (iv) heart rate sensors for measuring a user’s heart rate, (v) SpO2 sensors for measuring blood oxygen saturation and/or other biometric data of a user, (vi) capacitive sensors for detecting changes in potential at a portion of a user’s body (e.g., a sensor-skin interface), and/or (vii) light sensors (e.g., time-of-flight sensors, infrared light sensors, visible light sensors, etc.).

Biopotential-signal-sensing components may be devices used to measure electrical activity within the body (e.g., biopotential-signal sensors). Some types of biopotential-signal sensors include (i) electroencephalography (EEG) sensors configured to measure electrical activity in the brain to diagnose neurological disorders, (ii) electrocardiography (ECG or EKG) sensors configured to measure electrical activity of the heart to diagnose heart problems, (iii) electromyography (EMG) sensors configured to measure the electrical activity of muscles and to diagnose neuromuscular disorders, and (iv) electrooculography (EOG) sensors configured to measure the electrical activity of eye muscles to detect eye movement and diagnose eye disorders.

An application stored in memory of an electronic device (e.g., software) may include instructions stored in the memory. Examples of such applications include (i) games, (ii) word processors, (iii) messaging applications, (iv) media-streaming applications, (v) financial applications, (vi) calendars. (vii) clocks, and (viii) communication interface modules for enabling wired and/or wireless connections between different respective electronic devices (e.g., IEEE 1602.15.4, Wi-Fi, ZigBee, 6LoWPAN, Thread, Z-Wave, Bluetooth Smart, ISA100.11a, WirelessHART, or MiWi), custom or standard wired protocols (e.g., Ethernet or HomePlug), and/or any other suitable communication protocols).

A communication interface may be a mechanism that enables different systems or devices to exchange information and data with each other, including hardware, software, or a combination of both hardware and software. For example, a communication interface can refer to a physical connector and/or port on a device that enables communication with other devices (e.g., USB, Ethernet, HDMI, Bluetooth). In some embodiments, a communication interface can refer to a software layer that enables different software programs to communicate with each other (e.g., application programming interfaces (APIs), protocols like HTTP and TCP/IP, etc.).

A graphics module may be a component or software module that is designed to handle graphical operations and/or processes and can include a hardware module and/or a software module.

Non-transitory computer-readable storage media may be physical devices or storage media that can be used to store electronic data in a non-transitory form (e.g., such that the data is stored permanently until it is intentionally deleted or modified).

FIGS. 14 and 15 illustrate an example wrist-wearable device 1400 and an example computer system 1500, in accordance with some embodiments. Wrist-wearable device 1400 is an instance of wearable device 1002 described in FIG. 10 herein, such that the wearable device 1002 should be understood to have the features of the wrist-wearable device 1400 and vice versa. FIG. 15 illustrates components of the wrist-wearable device 1400, which can be used individually or in combination, including combinations that include other electronic devices and/or electronic components.

FIG. 14 shows a wearable band 1410 and a watch body 1420 (or capsule) being coupled, as discussed below, to form wrist-wearable device 1400. Wrist-wearable device 1400 can perform various functions and/or operations associated with navigating through user interfaces and selectively opening applications as well as the functions and/or operations described above with reference to FIGS. 10-13B.

As will be described in more detail below, operations executed by wrist-wearable device 1400 can include (i) presenting content to a user (e.g., displaying visual content via a display 1405), (ii) detecting (e.g., sensing) user input (e.g., sensing a touch on peripheral button 1423 and/or at a touch screen of the display 1405, a hand gesture detected by sensors (e.g., biopotential sensors)), (iii) sensing biometric data (e.g., neuromuscular signals, heart rate, temperature, sleep, etc.) via one or more sensors 1413, messaging (e.g., text, speech, video, etc.); image capture via one or more imaging devices or cameras 1425, wireless communications (e.g., cellular, near field, Wi-Fi, personal area network, etc.), location determination, financial transactions, providing haptic feedback, providing alarms, providing notifications, providing biometric authentication, providing health monitoring, providing sleep monitoring, etc.

The above-example functions can be executed independently in watch body 1420, independently in wearable band 1410, and/or via an electronic communication between watch body 1420 and wearable band 1410. In some embodiments, functions can be executed on wrist-wearable device 1400 while an AR environment is being presented (e.g., via one of AR systems 1000 to 1300). The wearable devices described herein can also be used with other types of AR environments.

Wearable band 1410 can be configured to be worn by a user such that an inner surface of a wearable structure 1411 of wearable band 1410 is in contact with the user’s skin. In this example, when worn by a user, sensors 1413 may contact the user’s skin. In some examples, one or more of sensors 1413 can sense biometric data such as a user’s heart rate, a saturated oxygen level, temperature, sweat level, neuromuscular signals, or a combination thereof. One or more of sensors 1413 can also sense data about a user’s environment including a user’s motion, altitude, location, orientation, gait, acceleration, position, or a combination thereof. In some embodiment, one or more of sensors 1413 can be configured to track a position and/or motion of wearable band 1410. One or more of sensors 1413 can include any of the sensors defined above and/or discussed below with respect to FIG. 14.

One or more of sensors 1413 can be distributed on an inside and/or an outside surface of wearable band 1410. In some embodiments, one or more of sensors 1413 are uniformly spaced along wearable band 1410. Alternatively, in some embodiments, one or more of sensors 1413 are positioned at distinct points along wearable band 1410. As shown in FIG. 14, one or more of sensors 1413 can be the same or distinct. For example, in some embodiments, one or more of sensors 1413 can be shaped as a pill (e.g., sensor 1413a), an oval, a circle a square, an oblong (e.g., sensor 1413c) and/or any other shape that maintains contact with the user’s skin (e.g., such that neuromuscular signal and/or other biometric data can be accurately measured at the user’s skin). In some embodiments, one or more sensors of 1413 are aligned to form pairs of sensors (e.g., for sensing neuromuscular signals based on differential sensing within each respective sensor). For example, sensor 1413b may be aligned with an adjacent sensor to form sensor pair 1414a and sensor 1413d may be aligned with an adjacent sensor to form sensor pair 1414b. In some embodiments, wearable band 1410 does not have a sensor pair. Alternatively, in some embodiments, wearable band 1410 has a predetermined number of sensor pairs (one pair of sensors, three pairs of sensors, four pairs of sensors, six pairs of sensors, sixteen pairs of sensors, etc.).

Wearable band 1410 can include any suitable number of sensors 1413. In some embodiments, the number and arrangement of sensors 1413 depends on the particular application for which wearable band 1410 is used. For instance, wearable band 1410 can be configured as an armband, wristband, or chest-band that include a plurality of sensors 1413 with different number of sensors 1413, a variety of types of individual sensors with the plurality of sensors 1413, and different arrangements for each use case, such as medical use cases as compared to gaming or general day-to-day use cases.

In accordance with some embodiments, wearable band 1410 further includes an electrical ground electrode and a shielding electrode. The electrical ground and shielding electrodes, like the sensors 1413, can be distributed on the inside surface of the wearable band 1410 such that they contact a portion of the user’s skin. For example, the electrical ground and shielding electrodes can be at an inside surface of a coupling mechanism 1416 or an inside surface of a wearable structure 1411. The electrical ground and shielding electrodes can be formed and/or use the same components as sensors 1413. In some embodiments, wearable band 1410 includes more than one electrical ground electrode and more than one shielding electrode.

Sensors 1413 can be formed as part of wearable structure 1411 of wearable band 1410. In some embodiments, sensors 1413 are flush or substantially flush with wearable structure 1411 such that they do not extend beyond the surface of wearable structure 1411. While flush with wearable structure 1411, sensors 1413 are still configured to contact the user’s skin (e.g., via a skin-contacting surface). Alternatively, in some embodiments, sensors 1413 extend beyond wearable structure 1411 a predetermined distance (e.g., 0.1 – 2 mm) to make contact and depress into the user’s skin. In some embodiment, sensors 1413 are coupled to an actuator (not shown) configured to adjust an extension height (e.g., a distance from the surface of wearable structure 1411) of sensors 1413 such that sensors 1413 make contact and depress into the user’s skin. In some embodiments, the actuators adjust the extension height between 0.01 mm – 1.2 mm. This may allow a user to customize the positioning of sensors 1413 to improve the overall comfort of the wearable band 1410 when worn while still allowing sensors 1413 to contact the user’s skin. In some embodiments, sensors 1413 are indistinguishable from wearable structure 1411 when worn by the user.

Wearable structure 1411 can be formed of an elastic material, elastomers, etc., configured to be stretched and fitted to be worn by the user. In some embodiments, wearable structure 1411 is a textile or woven fabric. As described above, sensors 1413 can be formed as part of a wearable structure 1411. For example, sensors 1413 can be molded into the wearable structure 1411, be integrated into a woven fabric (e.g., sensors 1413 can be sewn into the fabric and mimic the pliability of fabric and can and/or be constructed from a series woven strands of fabric).

Wearable structure 1411 can include flexible electronic connectors that interconnect sensors 1413, the electronic circuitry, and/or other electronic components (described below in reference to FIG. 15) that are enclosed in wearable band 1410. In some embodiments, the flexible electronic connectors are configured to interconnect sensors 1413, the electronic circuitry, and/or other electronic components of wearable band 1410 with respective sensors and/or other electronic components of another electronic device (e.g., watch body 1420). The flexible electronic connectors are configured to move with wearable structure 1411 such that the user adjustment to wearable structure 1411 (e.g., resizing, pulling, folding, etc.) does not stress or strain the electrical coupling of components of wearable band 1410.

As described above, wearable band 1410 is configured to be worn by a user. In particular, wearable band 1410 can be shaped or otherwise manipulated to be worn by a user.

For example, wearable band 1410 can be shaped to have a substantially circular shape such that it can be configured to be worn on the user’s lower arm or wrist. Alternatively, wearable band 1410 can be shaped to be worn on another body part of the user, such as the user’s upper arm (e.g., around a bicep), forearm, chest, legs, etc. Wearable band 1410 can include a retaining mechanism 1412 (e.g., a buckle, a hook and loop fastener, etc.) for securing wearable band 1410 to the user’s wrist or other body part. While wearable band 1410 is worn by the user, sensors 1413 sense data (referred to as sensor data) from the user’s skin. In some examples, sensors 1413 of wearable band 1410 obtain (e.g., sense and record) neuromuscular signals.

The sensed data (e.g., sensed neuromuscular signals) can be used to detect and/or determine the user’s intention to perform certain motor actions. In some examples, sensors 1413 may sense and record neuromuscular signals from the user as the user performs muscular activations (e.g., movements, gestures, etc.). The detected and/or determined motor actions (e.g., phalange (or digit) movements, wrist movements, hand movements, and/or other muscle intentions) can be used to determine control commands or control information (instructions to perform certain commands after the data is sensed) for causing a computing device to perform one or more input commands. For example, the sensed neuromuscular signals can be used to control certain user interfaces displayed on display 1405 of wrist-wearable device 1400 and/or can be transmitted to a device responsible for rendering an artificial-reality environment (e.g., a head-mounted display) to perform an action in an associated artificial-reality environment, such as to control the motion of a virtual device displayed to the user. The muscular activations performed by the user can include static gestures, such as placing the user’s hand palm down on a table, dynamic gestures, such as grasping a physical or virtual object, and covert gestures that are imperceptible to another person, such as slightly tensing a joint by co-contracting opposing muscles or using sub-muscular activations. The muscular activations performed by the user can include symbolic gestures (e.g., gestures mapped to other gestures, interactions, or commands, for example, based on a gesture vocabulary that specifies the mapping of gestures to commands).

The sensor data sensed by sensors 1413 can be used to provide a user with an enhanced interaction with a physical object (e.g., devices communicatively coupled with wearable band 1410) and/or a virtual object in an artificial-reality application generated by an artificial-reality system (e.g., user interface objects presented on the display 1405, or another computing device (e.g., a smartphone)).

In some embodiments, wearable band 1410 includes one or more haptic devices 1546 (e.g., a vibratory haptic actuator) that are configured to provide haptic feedback (e.g., a cutaneous and/or kinesthetic sensation, etc.) to the user’s skin. Sensors 1413 and/or haptic devices 1546 (shown in FIG. 15) can be configured to operate in conjunction with multiple applications including, without limitation, health monitoring, social media, games, and artificial reality (e.g., the applications associated with artificial reality).

Wearable band 1410 can also include coupling mechanism 1416 for detachably coupling a capsule (e.g., a computing unit) or watch body 1420 (via a coupling surface of the watch body 1420) to wearable band 1410. For example, a cradle or a shape of coupling mechanism 1416 can correspond to shape of watch body 1420 of wrist-wearable device 1400. In particular, coupling mechanism 1416 can be configured to receive a coupling surface proximate to the bottom side of watch body 1420 (e.g., a side opposite to a front side of watch body 1420 where display 1405 is located), such that a user can push watch body 1420 downward into coupling mechanism 1416 to attach watch body 1420 to coupling mechanism 1416. In some embodiments, coupling mechanism 1416 can be configured to receive a top side of the watch body 1420 (e.g., a side proximate to the front side of watch body 1420 where display 1405 is located) that is pushed upward into the cradle, as opposed to being pushed downward into coupling mechanism 1416. In some embodiments, coupling mechanism 1416 is an integrated component of wearable band 1410 such that wearable band 1410 and coupling mechanism 1416 are a single unitary structure. In some embodiments, coupling mechanism 1416 is a type of frame or shell that allows watch body 1420 coupling surface to be retained within or on wearable band 1410 coupling mechanism 1416 (e.g., a cradle, a tracker band, a support base, a clasp, etc.).

Coupling mechanism 1416 can allow for watch body 1420 to be detachably coupled to the wearable band 1410 through a friction fit, magnetic coupling, a rotation-based connector, a shear-pin coupler, a retention spring, one or more magnets, a clip, a pin shaft, a hook and loop fastener, or a combination thereof. A user can perform any type of motion to couple the watch body 1420 to wearable band 1410 and to decouple the watch body 1420 from the wearable band 1410. For example, a user can twist, slide, turn, push, pull, or rotate watch body 1420 relative to wearable band 1410, or a combination thereof, to attach watch body 1420 to wearable band 1410 and to detach watch body 1420 from wearable band 1410. Alternatively, as discussed below, in some embodiments, the watch body 1420 can be decoupled from the wearable band 1410 by actuation of a release mechanism 1429.

Wearable band 1410 can be coupled with watch body 1420 to increase the functionality of wearable band 1410 (e.g., converting wearable band 1410 into wrist-wearable device 1400, adding an additional computing unit and/or battery to increase computational resources and/or a battery life of wearable band 1410, adding additional sensors to improve sensed data, etc.). As described above, wearable band 1410 and coupling mechanism 1416 are configured to operate independently (e.g., execute functions independently) from watch body 1420. For example, coupling mechanism 1416 can include one or more sensors 1413 that contact a user’s skin when wearable band 1410 is worn by the user, with or without watch body 1420 and can provide sensor data for determining control commands.

A user can detach watch body 1420 from wearable band 1410 to reduce the encumbrance of wrist-wearable device 1400 to the user. For embodiments in which watch body 1420 is removable, watch body 1420 can be referred to as a removable structure, such that in these embodiments wrist-wearable device 1400 includes a wearable portion (e.g., wearable band 1410) and a removable structure (e.g., watch body 1420).

Turning to watch body 1420, in some examples watch body 1420 can have a substantially rectangular or circular shape. Watch body 1420 is configured to be worn by the user on their wrist or on another body part. More specifically, watch body 1420 is sized to be easily carried by the user, attached on a portion of the user’s clothing, and/or coupled to wearable band 1410 (forming the wrist-wearable device 1400). As described above, watch body 1420 can have a shape corresponding to coupling mechanism 1416 of wearable band 1410. In some embodiments, watch body 1420 includes a single release mechanism 1429 or multiple release mechanisms (e.g., two release mechanisms 1429 positioned on opposing sides of watch body 1420, such as spring-loaded buttons) for decoupling watch body 1420 from wearable band 1410. Release mechanism 1429 can include, without limitation, a button, a knob, a plunger, a handle, a lever, a fastener, a clasp, a dial, a latch, or a combination thereof.

A user can actuate release mechanism 1429 by pushing, turning, lifting, depressing, shifting, or performing other actions on release mechanism 1429. Actuation of release mechanism 1429 can release (e.g., decouple) watch body 1420 from coupling mechanism 1416 of wearable band 1410, allowing the user to use watch body 1420 independently from wearable band 1410 and vice versa. For example, decoupling watch body 1420 from wearable band 1410 can allow a user to capture images using rear-facing camera 1425b. Although release mechanism 1429 is shown positioned at a corner of watch body 1420, release mechanism 1429 can be positioned anywhere on watch body 1420 that is convenient for the user to actuate. In addition, in some embodiments, wearable band 1410 can also include a respective release mechanism for decoupling watch body 1420 from coupling mechanism 1416. In some embodiments, release mechanism 1429 is optional and watch body 1420 can be decoupled from coupling mechanism 1416 as described above (e.g., via twisting, rotating, etc.).

Watch body 1420 can include one or more peripheral buttons 1423 and 1427 for performing various operations at watch body 1420. For example, peripheral buttons 1423 and 1427 can be used to turn on or wake (e.g., transition from a sleep state to an active state) display 1405, unlock watch body 1420, increase or decrease a volume, increase or decrease a brightness, interact with one or more applications, interact with one or more user interfaces, etc. Additionally, or alternatively, in some embodiments, display 1405 operates as a touch screen and allows the user to provide one or more inputs for interacting with watch body 1420.

In some embodiments, watch body 1420 includes one or more sensors 1421. Sensors 1421 of watch body 1420 can be the same or distinct from sensors 1413 of wearable band 1410. Sensors 1421 of watch body 1420 can be distributed on an inside and/or an outside surface of watch body 1420. In some embodiments, sensors 1421 are configured to contact a user’s skin when watch body 1420 is worn by the user. For example, sensors 1421 can be placed on the bottom side of watch body 1420 and coupling mechanism 1416 can be a cradle with an opening that allows the bottom side of watch body 1420 to directly contact the user’s skin. Alternatively, in some embodiments, watch body 1420 does not include sensors that are configured to contact the user’s skin (e.g., including sensors internal and/or external to the watch body 1420 that are configured to sense data of watch body 1420 and the surrounding environment). In some embodiments, sensors 1421 are configured to track a position and/or motion of watch body 1420.

Watch body 1420 and wearable band 1410 can share data using a wired communication method (e.g., a Universal Asynchronous Receiver/Transmitter (UART), a USB transceiver, etc.) and/or a wireless communication method (e.g., near field communication, Bluetooth, etc.). For example, watch body 1420 and wearable band 1410 can share data sensed by sensors 1413 and 1421, as well as application and device specific information (e.g., active and/or available applications, output devices (e.g., displays, speakers, etc.), input devices (e.g., touch screens, microphones, imaging sensors, etc.).

In some embodiments, watch body 1420 can include, without limitation, a front-facing camera 1425a and/or a rear-facing camera 1425b, sensors 1421 (e.g., a biometric sensor, an IMU, a heart rate sensor, a saturated oxygen sensor, a neuromuscular signal sensor, an altimeter sensor, a temperature sensor, a bioimpedance sensor, a pedometer sensor, an optical sensor (e.g., imaging sensor 1563), a touch sensor, a sweat sensor, etc.). In some embodiments, watch body 1420 can include one or more haptic devices 1576 (e.g., a vibratory haptic actuator) that is configured to provide haptic feedback (e.g., a cutaneous and/or kinesthetic sensation, etc.) to the user. Sensors 1521 and/or haptic device 1576 can also be configured to operate in conjunction with multiple applications including, without limitation, health monitoring applications, social media applications, game applications, and artificial reality applications (e.g., the applications associated with artificial reality).

As described above, watch body 1420 and wearable band 1410, when coupled, can form wrist-wearable device 1400. When coupled, watch body 1420 and wearable band 1410 may operate as a single device to execute functions (operations, detections, communications, etc.) described herein. In some embodiments, each device may be provided with particular instructions for performing the one or more operations of wrist-wearable device 1400. For example, in accordance with a determination that watch body 1420 does not include neuromuscular signal sensors, wearable band 1410 can include alternative instructions for performing associated instructions (e.g., providing sensed neuromuscular signal data to watch body 1420 via a different electronic device). Operations of wrist-wearable device 1400 can be performed by watch body 1420 alone or in conjunction with wearable band 1410 (e.g., via respective processors and/or hardware components) and vice versa. In some embodiments, operations of wrist-wearable device 1400, watch body 1420, and/or wearable band 1410 can be performed in conjunction with one or more processors and/or hardware components.

As described below with reference to the block diagram of FIG. 15, wearable band 1410 and/or watch body 1420 can each include independent resources required to independently execute functions. For example, wearable band 1410 and/or watch body 1420 can each include a power source (e.g., a battery), a memory, data storage, a processor (e.g., a central processing unit (CPU)), communications, a light source, and/or input/output devices.

FIG. 15 shows block diagrams of a computing system 1530 corresponding to wearable band 1410 and a computing system 1560 corresponding to watch body 1420 according to some embodiments. Computing system 1500 of wrist-wearable device 1400 may include a combination of components of wearable band computing system 1530 and watch body computing system 1560, in accordance with some embodiments.

Watch body 1420 and/or wearable band 1410 can include one or more components shown in watch body computing system 1560. In some embodiments, a single integrated circuit may include all or a substantial portion of the components of watch body computing system 1560 included in a single integrated circuit. Alternatively, in some embodiments, components of the watch body computing system 1560 may be included in a plurality of integrated circuits that are communicatively coupled. In some embodiments, watch body computing system 1560 may be configured to couple (e.g., via a wired or wireless connection) with wearable band computing system 1530, which may allow the computing systems to share components, distribute tasks, and/or perform other operations described herein (individually or as a single device).

Watch body computing system 1560 can include one or more processors 1579, a controller 1577, a peripherals interface 1561, a power system 1595, and memory (e.g., a memory 1580).

Power system 1595 can include a charger input 1596, a power-management integrated circuit (PMIC) 1597, and a battery 1598. In some embodiments, a watch body 1420 and a wearable band 1410 can have respective batteries (e.g., battery 1598 and 1559) and can share power with each other. Watch body 1420 and wearable band 1410 can receive a charge using a variety of techniques. In some embodiments, watch body 1420 and wearable band 1410 can use a wired charging assembly (e.g., power cords) to receive the charge. Alternatively, or in addition, watch body 1420 and/or wearable band 1410 can be configured for wireless charging. For example, a portable charging device can be designed to mate with a portion of watch body 1420 and/or wearable band 1410 and wirelessly deliver usable power to battery 1598 of watch body 1420 and/or battery 1559 of wearable band 1410. Watch body 1420 and wearable band 1410 can have independent power systems (e.g., power system 1595 and 1556, respectively) to enable each to operate independently. Watch body 1420 and wearable band 1410 can also share power (e.g., one can charge the other) via respective PMICs (e.g., PMICs 1597 and 1558) and charger inputs (e.g., 1557 and 1596) that can share power over power and ground conductors and/or over wireless charging antennas.

In some embodiments, peripherals interface 1561 can include one or more sensors 1521. Sensors 1521 can include one or more coupling sensors 1562 for detecting when watch body 1420 is coupled with another electronic device (e.g., a wearable band 1410). Sensors 1521 can include one or more imaging sensors 1563 (e.g., one or more of cameras 1525, and/or separate imaging sensors 1563 (e.g., thermal-imaging sensors)). In some embodiments, sensors 1521 can include one or more SpO2 sensors 1564. In some embodiments, sensors 1521 can include one or more biopotential-signal sensors (e.g., EMG sensors 1565, which may be disposed on an interior, user-facing portion of watch body 1420 and/or wearable band 1410). In some embodiments, sensors 1521 may include one or more capacitive sensors 1566. In some embodiments, sensors 1521 may include one or more heart rate sensors 1567. In some embodiments, sensors 1521 may include one or more IMU sensors 1568. In some embodiments, one or more IMU sensors 1568 can be configured to detect movement of a user’s hand or other location where watch body 1420 is placed or held.

In some embodiments, one or more of sensors 1521 may provide an example human-machine interface. For example, a set of neuromuscular sensors, such as EMG sensors 1565, may be arranged circumferentially around wearable band 1410 with an interior surface of EMG sensors 1565 being configured to contact a user’s skin. Any suitable number of neuromuscular sensors may be used (e.g., between 2 and 20 sensors). The number and arrangement of neuromuscular sensors may depend on the particular application for which the wearable device is used. For example, wearable band 1410 can be used to generate control information for controlling an augmented reality system, a robot, controlling a vehicle, scrolling through text, controlling a virtual avatar, or any other suitable control task.

In some embodiments, neuromuscular sensors may be coupled together using flexible electronics incorporated into the wireless device, and the output of one or more of the sensing components can be optionally processed using hardware signal processing circuitry (e.g., to perform amplification, filtering, and/or rectification). In other embodiments, at least some signal processing of the output of the sensing components can be performed in software such as processors 1579. Thus, signal processing of signals sampled by the sensors can be performed in hardware, software, or by any suitable combination of hardware and software, as aspects of the technology described herein are not limited in this respect.

Neuromuscular signals may be processed in a variety of ways. For example, the output of EMG sensors 1565 may be provided to an analog front end, which may be configured to perform analog processing (e.g., amplification, noise reduction, filtering, etc.) on the recorded signals. The processed analog signals may then be provided to an analog-to-digital converter, which may convert the analog signals to digital signals that can be processed by one or more computer processors. Furthermore, although this example is as discussed in the context of interfaces with EMG sensors, the embodiments described herein can also be implemented in wearable interfaces with other types of sensors including, but not limited to, mechanomyography (MMG) sensors, sonomyography (SMG) sensors, and electrical impedance tomography (EIT) sensors.

In some embodiments, peripherals interface 1561 includes a near-field communication (NFC) component 1569, a global-position system (GPS) component 1570, a long-term evolution (LTE) component 1571, and/or a Wi-Fi and/or Bluetooth communication component 1572. In some embodiments, peripherals interface 1561 includes one or more buttons 1573 (e.g., peripheral buttons 1423 and 1427 in FIG. 14), which, when selected by a user, cause operation to be performed at watch body 1420. In some embodiments, the peripherals interface 1561 includes one or more indicators, such as a light emitting diode (LED), to provide a user with visual indicators (e.g., message received, low battery, active microphone and/or camera, etc.).

Watch body 1420 can include at least one display 1405 for displaying visual representations of information or data to a user, including user-interface elements and/or three-dimensional virtual objects. The display can also include a touch screen for inputting user inputs, such as touch gestures, swipe gestures, and the like. Watch body 1420 can include at least one speaker 1574 and at least one microphone 1575 for providing audio signals to the user and receiving audio input from the user. The user can provide user inputs through microphone 1575 and can also receive audio output from speaker 1574 as part of a haptic event provided by haptic controller 1578. Watch body 1420 can include at least one camera 1525, including a front camera 1525a and a rear camera 1525b. Cameras 1525 can include ultra-wide-angle cameras, wide angle cameras, fish-eye cameras, spherical cameras, telephoto cameras, depth-sensing cameras, or other types of cameras.

Watch body computing system 1560 can include one or more haptic controllers 1578 and associated componentry (e.g., haptic devices 1576) for providing haptic events at watch body 1420 (e.g., a vibrating sensation or audio output in response to an event at the watch body 1420). Haptic controllers 1578 can communicate with one or more haptic devices 1576, such as electroacoustic devices, including a speaker of the one or more speakers 1574 and/or other audio components and/or electromechanical devices that convert energy into linear motion such as a motor, solenoid, electroactive polymer, piezoelectric actuator, electrostatic actuator, or other tactile output generating components (e.g., a component that converts electrical signals into tactile outputs on the device). Haptic controller 1578 can provide haptic events to that are capable of being sensed by a user of watch body 1420. In some embodiments, one or more haptic controllers 1578 can receive input signals from an application of applications 1582.

In some embodiments, wearable band computing system 1530 and/or watch body computing system 1560 can include memory 1580, which can be controlled by one or more memory controllers of controllers 1577. In some embodiments, software components stored in memory 1580 include one or more applications 1582 configured to perform operations at the watch body 1420. In some embodiments, one or more applications 1582 may include games, word processors, messaging applications, calling applications, web browsers, social media applications, media streaming applications, financial applications, calendars, clocks, etc. In some embodiments, software components stored in memory 1580 include one or more communication interface modules 1583 as defined above. In some embodiments, software components stored in memory 1580 include one or more graphics modules 1584 for rendering, encoding, and/or decoding audio and/or visual data and one or more data management modules 1585 for collecting, organizing, and/or providing access to data 1587 stored in memory 1580. In some embodiments, one or more of applications 1582 and/or one or more modules can work in conjunction with one another to perform various tasks at the watch body 1420.

In some embodiments, software components stored in memory 1580 can include one or more operating systems 1581 (e.g., a Linux-based operating system, an Android operating system, etc.). Memory 1580 can also include data 1587. Data 1587 can include profile data 1588A, sensor data 1589A, media content data 1590, and application data 1591.

It should be appreciated that watch body computing system 1560 is an example of a computing system within watch body 1420, and that watch body 1420 can have more or fewer components than shown in watch body computing system 1560, can combine two or more components, and/or can have a different configuration and/or arrangement of the components. The various components shown in watch body computing system 1560 are implemented in hardware, software, firmware, or a combination thereof, including one or more signal processing and/or application-specific integrated circuits.

Turning to the wearable band computing system 1530, one or more components that can be included in wearable band 1410 are shown. Wearable band computing system 1530 can include more or fewer components than shown in watch body computing system 1560, can combine two or more components, and/or can have a different configuration and/or arrangement of some or all of the components. In some embodiments, all, or a substantial portion of the components of wearable band computing system 1530 are included in a single integrated circuit. Alternatively, in some embodiments, components of wearable band computing system 1530 are included in a plurality of integrated circuits that are communicatively coupled. As described above, in some embodiments, wearable band computing system 1530 is configured to couple (e.g., via a wired or wireless connection) with watch body computing system 1560, which allows the computing systems to share components, distribute tasks, and/or perform other operations described herein (individually or as a single device).

Wearable band computing system 1530, similar to watch body computing system 1560, can include one or more processors 1549, one or more controllers 1547 (including one or more haptics controllers 1548), a peripherals interface 1531 that can includes one or more sensors 1513 and other peripheral devices, a power source (e.g., a power system 1556), and memory (e.g., a memory 1550) that includes an operating system (e.g., an operating system 1551), data (e.g., data 1554 including profile data 1588B, sensor data 1589B, etc.), and one or more modules (e.g., a communications interface module 1552, a data management module 1553, etc.).

One or more of sensors 1513 can be analogous to sensors 1521 of watch body computing system 1560. For example, sensors 1513 can include one or more coupling sensors 1532, one or more SpO2 sensors 1534, one or more EMG sensors 1535, one or more capacitive sensors 1536, one or more heart rate sensors 1537, and one or more IMU sensors 1538.

Peripherals interface 1531 can also include other components analogous to those included in peripherals interface 1561 of watch body computing system 1560, including an NFC component 1539, a GPS component 1540, an LTE component 1541, a Wi-Fi and/or Bluetooth communication component 1542, and/or one or more haptic devices 1546 as described above in reference to peripherals interface 1561. In some embodiments, peripherals interface 1531 includes one or more buttons 1543, a display 1533, a speaker 1544, a microphone 1545, and a camera 1555. In some embodiments, peripherals interface 1531 includes one or more indicators, such as an LED.

It should be appreciated that wearable band computing system 1530 is an example of a computing system within wearable band 1410, and that wearable band 1410 can have more or fewer components than shown in wearable band computing system 1530, combine two or more components, and/or have a different configuration and/or arrangement of the components. The various components shown in wearable band computing system 1530 can be implemented in one or more of a combination of hardware, software, or firmware, including one or more signal processing and/or application-specific integrated circuits.

Wrist-wearable device 1400 with respect to FIG. 14 is an example of wearable band 1410 and watch body 1420 coupled together, so wrist-wearable device 1400 will be understood to include the components shown and described for wearable band computing system 1530 and watch body computing system 1560. In some embodiments, wrist-wearable device 1400 has a split architecture (e.g., a split mechanical architecture, a split electrical architecture, etc.) between watch body 1420 and wearable band 1410. In other words, all of the components shown in wearable band computing system 1530 and watch body computing system 1560 can be housed or otherwise disposed in a combined wrist-wearable device 1400 or within individual components of watch body 1420, wearable band 1410, and/or portions thereof (e.g., a coupling mechanism 1416 of wearable band 1410).

The techniques described above can be used with any device for sensing neuromuscular signals but could also be used with other types of wearable devices for sensing neuromuscular signals (such as body-wearable or head-wearable devices that might have neuromuscular sensors closer to the brain or spinal column).

In some embodiments, wrist-wearable device 1400 can be used in conjunction with a head-wearable device (e.g., AR system 1600 and VR system 1700) and/or an HIPD, and wrist-wearable device 1400 can also be configured to be used to allow a user to control any aspect of the artificial reality (e.g., by using EMG-based gestures to control user interface objects in the artificial reality and/or by allowing a user to interact with the touchscreen on the wrist-wearable device to also control aspects of the artificial reality). Having thus described example wrist-wearable devices, attention will now be turned to example head-wearable devices, such AR system 1600 and VR system 1700.

FIGS. 16 to 18 show example artificial-reality systems, which can be used as or in connection with wrist-wearable device 1400. In some embodiments, AR system 1600 includes an eyewear device 1602, as shown in FIG. 16. In some embodiments, VR system 1700 includes a head-mounted display (HMD) 1712, as shown in FIGS. 17A and 17B. In some embodiments, AR system 1600 and VR system 1700 can include one or more analogous components (e.g., components for presenting interactive artificial-reality environments, such as processors, memory, and/or presentation devices, including one or more displays and/or one or more

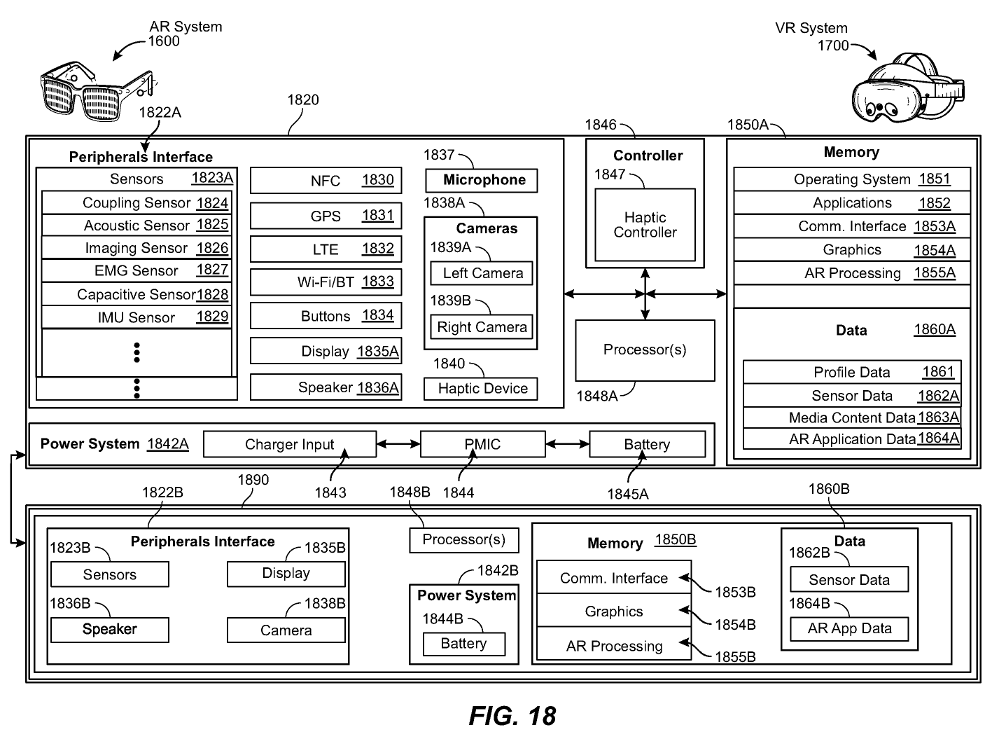

waveguides), some of which are described in more detail with respect to FIG. 18. As described herein, a head-wearable device can include components of eyewear device 1602 and/or head-mounted display 1712. Some embodiments of head-wearable devices do not include any displays, including any of the displays described with respect to AR system 1600 and/or VR system 1700. While the example artificial-reality systems are respectively described herein as AR system 1600 and VR system 1700, either or both of the example AR systems described herein can be configured to present fully-immersive virtual-reality scenes presented in substantially all of a user’s field of view or subtler augmented-reality scenes that are presented within a portion, less than all, of the user’s field of view.

FIG. 16 show an example visual depiction of AR system 1600, including an eyewear device 1602 (which may also be described herein as augmented-reality glasses, and/or smart glasses). AR system 1600 can include additional electronic components that are not shown in FIG. 16, such as a wearable accessory device and/or an intermediary processing device, in electronic communication or otherwise configured to be used in conjunction with the eyewear device 1602. In some embodiments, the wearable accessory device and/or the intermediary processing device may be configured to couple with eyewear device 1602 via a coupling mechanism in electronic communication with a coupling sensor 1824 (FIG. 18), where coupling sensor 1824 can detect when an electronic device becomes physically or electronically coupled with eyewear device 1602. In some embodiments, eyewear device 1602 can be configured to couple to a housing 1890 (FIG. 18), which may include one or more additional coupling mechanisms configured to couple with additional accessory devices. The components shown in FIG. 16 can be implemented in hardware, software, firmware, or a combination thereof, including one or more signal-processing components and/or application-specific integrated circuits (ASICs).

Eyewear device 1602 includes mechanical glasses components, including a frame 1604 configured to hold one or more lenses (e.g., one or both lenses 1606-1 and 1606-2). One of ordinary skill in the art will appreciate that eyewear device 1602 can include additional mechanical components, such as hinges configured to allow portions of frame 1604 of eyewear device 1602 to be folded and unfolded, a bridge configured to span the gap between lenses 1606-1 and 1606-2 and rest on the user’s nose, nose pads configured to rest on the bridge of the nose and provide support for eyewear device 1602, earpieces configured to rest on the user’s ears and provide additional support for eyewear device 1602, temple arms configured to extend from the hinges to the earpieces of eyewear device 1602, and the like. One of ordinary skill in the art will further appreciate that some examples of AR system 1600 can include none of the mechanical components described herein. For example, smart contact lenses configured to present artificial reality to users may not include any components of eyewear device 1602.

Eyewear device 1602 includes electronic components, many of which will be described in more detail below with respect to FIG. 10. Some example electronic components are illustrated in FIG. 16, including acoustic sensors 1625-1, 1625-2, 1625-3, 1625-4, 1625-5, and 1625-6, which can be distributed along a substantial portion of the frame 1604 of eyewear device 1602. Eyewear device 1602 also includes a left camera 1639A and a right camera 1639B, which are located on different sides of the frame 1604. Eyewear device 1602 also includes a processor 1648 (or any other suitable type or form of integrated circuit) that is embedded into a portion of the frame 1604.

FIGS. 17A and 17B show a VR system 1700 that includes a head-mounted display (HMD) 1712 (e.g., also referred to herein as an artificial-reality headset, a head-wearable device, a VR headset, etc.), in accordance with some embodiments. As noted, some artificial-reality systems (e.g., AR system 1600) may, instead of blending an artificial reality with actual reality, substantially replace one or more of a user’s visual and/or other sensory perceptions of the real world with a virtual experience (e.g., AR systems 1200 and 1300).

HMD 1712 includes a front body 1714 and a frame 1716 (e.g., a strap or band) shaped to fit around a user’s head. In some embodiments, front body 1714 and/or frame 1716 include one or more electronic elements for facilitating presentation of and/or interactions with an AR and/or VR system (e.g., displays, IMUs, tracking emitter or detectors). In some embodiments, HMD 1712 includes output audio transducers (e.g., an audio transducer 1718), as shown in FIG. 17B. In some embodiments, one or more components, such as the output audio transducer(s) 1718 and frame 1716, can be configured to attach and detach (e.g., are detachably attachable) to HMD 1712 (e.g., a portion or all of frame 1716, and/or audio transducer 1718), as shown in FIG. 17B. In some embodiments, coupling a detachable component to HMD 1712 causes the detachable component to come into electronic communication with HMD 1712.

FIGS. 17A and 17B also show that VR system 1700 includes one or more cameras, such as left camera 1739A and right camera 1739B, which can be analogous to left and right cameras 1639A and 1639B on frame 1604 of eyewear device 1602. In some embodiments, VR system 1700 includes one or more additional cameras (e.g., cameras 1739C and 1739D), which can be configured to augment image data obtained by left and right cameras 1739A and 1739B by providing more information. For example, camera 1739C can be used to supply color information that is not discerned by cameras 1739A and 1739B. In some embodiments, one or more of cameras 1739A to 1739D can include an optional IR cut filter configured to remove IR light from being received at the respective camera sensors.

FIG. 18 illustrates a computing system 1820 and an optional housing 1890, each of which show components that can be included in AR system 1600 and/or VR system 1700. In some embodiments, more or fewer components can be included in optional housing 1890 depending on practical restraints of the respective AR system being described.

In some embodiments, computing system 1820 can include one or more peripherals interfaces 1822A and/or optional housing 1890 can include one or more peripherals interfaces 1822B. Each of computing system 1820 and optional housing 1890 can also include one or more power systems 1842A and 1842B, one or more controllers 1846 (including one or more haptic controllers 1847), one or more processors 1848A and 1848B (as defined above, including any of the examples provided), and memory 1850A and 1850B, which can all be in electronic communication with each other. For example, the one or more processors 1848A and 1848B can be configured to execute instructions stored in memory 1850A and 1850B, which can cause a controller of one or more of controllers 1846 to cause operations to be performed at one or more peripheral devices connected to peripherals interface 1822A and/or 1822B. In some embodiments, each operation described can be powered by electrical power provided by power system 1842A and/or 1842B.

In some embodiments, peripherals interface 1822A can include one or more devices configured to be part of computing system 1820, some of which have been defined above and/or described with respect to the wrist-wearable devices shown in FIGS. 14 and 15. For example, peripherals interface 1822A can include one or more sensors 1823A. Some example sensors 1823A include one or more coupling sensors 1824, one or more acoustic sensors 1825, one or more imaging sensors 1826, one or more EMG sensors 1827, one or more capacitive sensors 1828, one or more IMU sensors 1829, and/or any other types of sensors explained above or described with respect to any other embodiments discussed herein.

In some embodiments, peripherals interfaces 1822A and 1822B can include one or more additional peripheral devices, including one or more NFC devices 1830, one or more GPS devices 1831, one or more LTE devices 1832, one or more Wi-Fi and/or Bluetooth devices 1833, one or more buttons 1834 (e.g., including buttons that are slidable or otherwise adjustable), one or more displays 1835A and 1835B, one or more speakers 1836A and 1836B, one or more microphones 1837, one or more cameras 1838A and 1838B (e.g., including the left camera 1839A and/or a right camera 1839B), one or more haptic devices 1840, and/or any other types of peripheral devices defined above or described with respect to any other embodiments discussed herein.

AR systems can include a variety of types of visual feedback mechanisms (e.g., presentation devices). For example, display devices in AR system 1600 and/or VR system 1700 can include one or more liquid-crystal displays (LCDs), light emitting diode (LED) displays, organic LED (OLED) displays, and/or any other suitable types of display screens. Artificial-reality systems can include a single display screen (e.g., configured to be seen by both eyes), and/or can provide separate display screens for each eye, which can allow for additional flexibility for varifocal adjustments and/or for correcting a refractive error associated with a user’s vision. Some embodiments of AR systems also include optical subsystems having one or more lenses (e.g., conventional concave or convex lenses, Fresnel lenses, or adjustable liquid lenses) through which a user can view a display screen.

For example, respective displays 1835A and 1835B can be coupled to each of the lenses 1606-1 and 1606-2 of AR system 1600. Displays 1835A and 1835B may be coupled to each of lenses 1606-1 and 1606-2, which can act together or independently to present an image or series of images to a user. In some embodiments, AR system 1600 includes a single display 1835A or 1835B (e.g., a near-eye display) or more than two displays 1835A and 1835B. In some embodiments, a first set of one or more displays 1835A and 1835B can be used to present an augmented-reality environment, and a second set of one or more display devices 1835A and 1835B can be used to present a virtual-reality environment. In some embodiments, one or more waveguides are used in conjunction with presenting artificial-reality content to the user of AR system 1600 (e.g., as a means of delivering light from one or more displays 1835A and 1835B to the user’s eyes). In some embodiments, one or more waveguides are fully or partially integrated into the eyewear device 1602. Additionally, or alternatively to display screens, some artificial-reality systems include one or more projection systems. For example, display devices in AR system 1600 and/or VR system 1700 can include micro-LED projectors that project light (e.g., using a waveguide) into display devices, such as clear combiner lenses that allow ambient light to pass through. The display devices can refract the projected light toward a user’s pupil and can enable a user to simultaneously view both artificial-reality content and the real world. Artificial-reality systems can also be configured with any other suitable type or form of image projection system. In some embodiments, one or more waveguides are provided additionally or alternatively to the one or more display(s) 1835A and 1835B.

Computing system 1820 and/or optional housing 1890 of AR system 1600 or VR system 1700 can include some or all of the components of a power system 1842A and 1842B. Power systems 1842A and 1842B can include one or more charger inputs 1843, one or more PMICs 1844, and/or one or more batteries 1845A and 1844B.

Memory 1850A and 1850B may include instructions and data, some or all of which may be stored as non-transitory computer-readable storage media within the memories 1850A and 1850B. For example, memory 1850A and 1850B can include one or more operating systems 1851, one or more applications 1852, one or more communication interface applications 1853A and 1853B, one or more graphics applications 1854A and 1854B, one or more AR processing applications 1855A and 1855B, and/or any other types of data defined above or described with respect to any other embodiments discussed herein.

Memory 1850A and 1850B also include data 1860A and 1860B, which can be used in conjunction with one or more of the applications discussed above. Data 1860A and 1860B can include profile data 1861, sensor data 1862A and 1862B, media content data 1863A, AR application data 1864A and 1864B, and/or any other types of data defined above or described with respect to any other embodiments discussed herein.

In some embodiments, controller 1846 of eyewear device 1602 may process information generated by sensors 1823A and/or 1823B on eyewear device 1602 and/or another electronic device within AR system 1600. For example, controller 1846 can process information from acoustic sensors 1625-1 and 1625-2. For each detected sound, controller 1846 can perform a direction of arrival (DOA) estimation to estimate a direction from which the detected sound arrived at eyewear device 1602 of AR system 1600. As one or more of acoustic sensors 1825 (e.g., the acoustic sensors 1625-1, 1625-2) detects sounds, controller 1846 can populate an audio data set with the information (e.g., represented as sensor data 1862A and 1862B).

In some embodiments, a physical electronic connector can convey information between eyewear device 1602 and another electronic device and/or between one or more processors 1648, 1848A, 1848B of AR system 1600 or VR system 1700 and controller 1846. The information can be in the form of optical data, electrical data, wireless data, or any other transmittable data form. Moving the processing of information generated by eyewear device 1602 to an intermediary processing device can reduce weight and heat in the eyewear device, making it more comfortable and safer for a user. In some embodiments, an optional wearable accessory device (e.g., an electronic neckband) is coupled to eyewear device 1602 via one or more connectors. The connectors can be wired or wireless connectors and can include electrical and/or non-electrical (e.g., structural) components. In some embodiments, eyewear device 1602 and the wearable accessory device can operate independently without any wired or wireless connection between them.

In some situations, pairing external devices, such as an intermediary processing device (e.g., HIPD 1006, 1106, 1206) with eyewear device 1602 (e.g., as part of AR system 1600) enables eyewear device 1602 to achieve a similar form factor of a pair of glasses while still providing sufficient battery and computation power for expanded capabilities. Some, or all, of the battery power, computational resources, and/or additional features of AR system 1600 can be provided by a paired device or shared between a paired device and eyewear device 1602, thus reducing the weight, heat profile, and form factor of eyewear device 1602 overall while allowing eyewear device 1602 to retain its desired functionality. For example, the wearable accessory device can allow components that would otherwise be included on eyewear device 1602 to be included in the wearable accessory device and/or intermediary processing device, thereby shifting a weight load from the user’s head and neck to one or more other portions of the user’s body. In some embodiments, the intermediary processing device has a larger surface area over which to diffuse and disperse heat to the ambient environment. Thus, the intermediary processing device can allow for greater battery and computation capacity than might otherwise have been possible on eyewear device 1602 standing alone. Because weight carried in the wearable accessory device can be less invasive to a user than weight carried in the eyewear device 1602, a user may tolerate wearing a lighter eyewear device and carrying or wearing the paired device for greater lengths of time than the user would tolerate wearing a heavier eyewear device standing alone, thereby enabling an artificial-reality environment to be incorporated more fully into a user’s day-to-day activities.

AR systems can include various types of computer vision components and subsystems. For example, AR system 1600 and/or VR system 1700 can include one or more optical sensors such as two-dimensional (2D) or three-dimensional (3D) cameras, time-of-flight depth sensors, structured light transmitters and detectors, single-beam or sweeping laser rangefinders, 3D LiDAR sensors, and/or any other suitable type or form of optical sensor. An AR system can process data from one or more of these sensors to identify a location of a user and/or aspects of the use’s real-world physical surroundings, including the locations of real-world objects within the real-world physical surroundings. In some embodiments, the methods described herein are used to map the real world, to provide a user with context about real-world surroundings, and/or to generate digital twins (e.g., interactable virtual objects), among a variety of other functions. For example, FIGS. 17A and 17B show VR system 1700 having cameras 1739A to 1739D, which can be used to provide depth information for creating a voxel field and a two-dimensional mesh to provide object information to the user to avoid collisions.

In some embodiments, AR system 1600 and/or VR system 1700 can include haptic (tactile) feedback systems, which may be incorporated into headwear, gloves, body suits, handheld controllers, environmental devices (e.g., chairs or floormats), and/or any other type of device or system, such as the wearable devices discussed herein. The haptic feedback systems may provide various types of cutaneous feedback, including vibration, force, traction, shear, texture, and/or temperature. The haptic feedback systems may also provide various types of kinesthetic feedback, such as motion and compliance. The haptic feedback may be implemented using motors, piezoelectric actuators, fluidic systems, and/or a variety of other types of feedback mechanisms. The haptic feedback systems may be implemented independently of other artificial-reality devices, within other artificial-reality devices, and/or in conjunction with other artificial-reality devices.

In some embodiments of an artificial reality system, such as AR system 1600 and/or VR system 1700, ambient light (e.g., a live feed of the surrounding environment that a user would normally see) can be passed through a display element of a respective head-wearable device presenting aspects of the AR system. In some embodiments, ambient light can be passed through a portion less that is less than all of an AR environment presented within a user’s field of view (e.g., a portion of the AR environment co-located with a physical object in the user’s real-world environment that is within a designated boundary (e.g., a guardian boundary) configured to be used by the user while they are interacting with the AR environment). For example, a visual user interface element (e.g., a notification user interface element) can be presented at the head-wearable device, and an amount of ambient light (e.g., 15-50% of the ambient light) can be passed through the user interface element such that the user can distinguish at least a portion of the physical environment over which the user interface element is being displayed.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed.

The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

As used herein, the term “substantially” in reference to a given parameter, property, or condition may mean and include to a degree that one of ordinary skill in the art would understand that the given parameter, property, or condition is met with a small degree of variance, such as within acceptable manufacturing tolerances. By way of example, depending on the particular parameter, property, or condition that is substantially met, the parameter, property, or condition may be at least approximately 90% met, at least approximately 95% met, or even at least approximately 99% met.

As used herein, the term “approximately” in reference to a particular numeric value or range of values may, in certain embodiments, mean and include the stated value as well as all values within 10% of the stated value. Thus, by way of example, reference to the numeric value “50” as “approximately 50” may, in certain embodiments, include values equal to 50±5, i.e., values within the range 45 to 55.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

It will be understood that when an element such as a layer or a region is referred to as being formed on, deposited on, or disposed “on” or “over” another element, it may be located directly on at least a portion of the other element, or one or more intervening elements may also be present. In contrast, when an element is referred to as being “directly on” or “directly over” another element, it may be located on at least a portion of the other element, with no intervening elements present.

While various features, elements or steps of particular embodiments may be disclosed using the transitional phrase “comprising,” it is to be understood that alternative embodiments, including those that may be described using the transitional phrases “consisting of” or “consisting essentially of,” are implied. Thus, for example, implied alternative embodiments to an organic solid crystal material that comprises or includes anthracene include embodiments where an organic solid crystal material consists essentially of anthracene and embodiments where an organic solid crystal material consists of anthracene.

What is claimed is:

1. An organic solid crystal material comprising:
a particulate solid body having a crystalline structure comprising an organic compound;
a particle size of the particulate solid body ranging from 10 nm to 10 μm; and
a refractive index of 1.5 to 3.5 along at least one dimension of the particulate solid body.

2. The organic solid crystal material of claim 1, wherein the particulate solid body has a shape selected from the group consisting of spherical, platelet, disk, and rod.

3. The organic solid crystal material of claim 1, wherein the particulate solid body is optically anisotropic.

4. The organic solid crystal material of claim 1, wherein the particulate solid body has a major length and the refractive index is greatest along the major length.

5. The organic solid crystal material of claim 1, wherein the crystalline structure has a density ranging from approximately 1.1 to approximately 2 g/cm³.

6. The organic solid crystal material of claim 1, wherein the organic compound comprises at least one of anthracene, phenanthrene, pyrene, corannulene, fluorene, and biphenyl.

7. An article comprising:
a solid body having a polycrystalline structure comprising an organic compound,
wherein the solid body has a density of 1.1 to 2 g/cm³ and
an average refractive index of 1.5 to 3.5.

8. The article of claim 7, wherein the solid body comprises a non-planar surface.

9. The article of claim 7, wherein the solid body comprises a planar surface.

10. The article of claim 7, wherein the solid body is optically isotropic.

11. The article of claim 7, wherein the solid body is optically anisotropic.

12. The article of claim 1, wherein the solid body has a visible spectrum transmittance of at least 80% and a near infrared spectrum transmittance of at least 60%.

13. The article of claim 7, wherein the solid body comprises less than 10% bulk haze and a yellowness index |b*| less than 0.5 per 50 μm.

14. The article of claim 7, wherein the solid body comprises sintered particles each having a crystalline structure and comprising an organic compound.

15. The article of claim 7, wherein the solid body comprises an average grain size of 20 nanometers to 1 micrometer.

16. A method comprising:
forming a green body comprising particles of an organic solid crystal material; and
heating the green body to a sintering temperature effective to densify the particles and form an optical element.

17. The method of claim 16, wherein the green body comprises a sintering aid.

18. The method of claim 16, wherein the green body is free of a sintering aid.

19. The method of claim 16, wherein heating the green body comprises spark plasma sintering.

20. The method of claim 16, wherein the sintering temperature is less than a melting temperature of the organic solid crystal material.
